(19) United States
(12) Patent Application Publication
(10) Pub. No.: US 2025/0212435 A1
(43) Pub. Date: Jun. 26, 2025

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Hidenori FUJII, Tokyo (JP); Masahiro UJIKE, Tokyo (JP); Shunsuke NODA, Fukuoka (JP)

(73) Assignee: Mitsubishi Electric Corporation, Tokyo (JP)

(21) Appl. No.: 18/908,764

(22) Filed: Oct. 7, 2024

(30) Foreign Application Priority Data
Dec. 21, 2023 (JP) 2023-215833

(51) Int. Cl. H01L 29/739; H01L 27/07; H01L 29/06; H01L 29/423; H01L 29/66; H01L 29/861

(52) U.S. Cl. CPC H10D 12/481; H10D 8/00; H10D 12/038; H10D 62/127; H10D 64/513; H10D 84/811

(57) ABSTRACT

A semiconductor device includes a semiconductor substrate, an electrode, and a first silicon nodule. The semiconductor substrate includes a drift layer of a first conductivity type and an anode layer of a second conductivity type, and the anode layer is provided on at least a part of the drift layer. The electrode is provided above the anode layer and contains aluminum. The first silicon nodule is provided between the anode layer and the electrode and contains oxygen.

### BACKGROUND OF THE INVENTION

### Field of the Invention

The present disclosure relates to a semiconductor device and a method of manufacturing a semiconductor device.

### Description of the Background Art

In recent years, in an RC-IGBT provided with an IGBT region and a diode region, there is proposed a configuration in which an electrode containing aluminum is provided near an anode layer of the diode region (for example, Japanese Patent Application No. 2022-56498).

In the configuration in which the electrode containing aluminum is provided near the anode layer as in Japanese Patent Application No. 2022-56498, there is an effect that diffusion of aluminum having a high diffusion coefficient and contained in the electrode is enhanced in the anode layer containing silicon. For this reason, there is a problem that variation in a diffusion profile of the anode layer increases.

### SUMMARY

The present disclosure has been made in view of the above problems, and an object thereof is to provide a technique capable of suppressing interdiffusion between silicon and aluminum.

A semiconductor device according to the present disclosure includes: a semiconductor substrate that includes a drift layer of a first conductivity type and an anode layer of a second conductivity type provided on at least a part of the drift layer; an electrode provided above the anode layer and containing aluminum; and a first silicon nodule provided between the anode layer and the electrode and containing oxygen.

The interdiffusion between silicon and aluminum can be suppressed.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a configuration of a semiconductor device according to a first preferred embodiment;

FIG. 2 is a plan view illustrating another configuration of the semiconductor device according to the first preferred embodiment;

FIG. 3 is a partially enlarged plan view illustrating a configuration of an IGBT region of the semiconductor device according to the first preferred embodiment;

FIGS. 4 and 5 are cross-sectional views each illustrating the configuration of the IGBT region of the semiconductor device according to the first preferred embodiment;

FIG. 6 is a partially enlarged plan view illustrating a configuration of a diode region of the semiconductor device according to the first preferred embodiment;

FIGS. 7 and 8 are cross-sectional views each illustrating a configuration of a diode region of the semiconductor device according to the first preferred embodiment;

FIG. 9 is a cross-sectional view illustrating a configuration of a boundary region between the IGBT region and the diode region of the semiconductor device according to the first preferred embodiment;

FIG. 10 is a view illustrating a relationship between a depth from a back surface, an impurity concentration, and a carrier density in an on state in the IGBT region according to the first preferred embodiment;

FIGS. 11 to 12B are cross-sectional views each illustrating a configuration of a termination region of the semiconductor device according to the first preferred embodiment;

FIGS. 13A to 18B are cross-sectional views each illustrating a method of manufacturing the semiconductor device according to the first preferred embodiment;

FIG. 19 is a flowchart illustrating the method of manufacturing the semiconductor device according to the first preferred embodiment;

FIG. 20 is a cross-sectional view illustrating a configuration of a boundary region between an IGBT region and a diode region of a semiconductor device according to a second preferred embodiment;

FIG. 21 is a view illustrating a result of an oxygen concentration in a method of manufacturing the semiconductor device according to the second preferred embodiment;

FIG. 22 is a cross-sectional view illustrating a configuration of a boundary region between an IGBT region and a diode region of a semiconductor device according to a third preferred embodiment;

FIG. 23 is a cross-sectional view illustrating a configuration of a boundary region between an IGBT region and a diode region of a semiconductor device according to a fourth preferred embodiment;

FIG. 24 is a cross-sectional view illustrating a configuration of a boundary region between an IGBT region and a diode region of a semiconductor device according to a fifth preferred embodiment;

FIG. 25 is a cross-sectional view illustrating a configuration of a boundary region between an IGBT region and a diode region of a semiconductor device according to a sixth preferred embodiment;

FIG. 26 is a cross-sectional view illustrating a configuration of a boundary region between an IGBT region and a diode region of a semiconductor device according to a seventh preferred embodiment;

FIG. 27 is a cross-sectional view illustrating a configuration of a boundary region between an IGBT region and a diode region of a semiconductor device according to an eighth preferred embodiment;

FIG. 28 is a cross-sectional view illustrating a configuration of a boundary region between an IGBT region and a diode region of a semiconductor device according to a ninth preferred embodiment;

FIG. 29 is a cross-sectional view illustrating a configuration of a boundary region between an IGBT region and a diode region of a semiconductor device according to a tenth preferred embodiment; and

FIG. 30 is a cross-sectional view illustrating a configuration of a boundary region between an IGBT region and a diode region of a semiconductor device according to an eleventh preferred embodiment.

### DESCRIPTION OF THE PREFERRED EMBODIMENTS

Hereinafter, preferred embodiments will be described with reference to the accompanying drawings. Features described in the following preferred embodiments are examples, and all the features are not necessarily essential. In the following description, similar constituent elements in a plurality of preferred embodiments are denoted by the same or similar reference numerals, and different constituent elements will be mainly described. In the following description, specific positions and directions such as “upper”, “lower”, “left”, “right”, “front”, and “back” do not necessarily coincide with actual positions and directions in practice. In addition, the fact that a certain portion has a higher concentration than another portion means that, for example, an average of concentrations of the certain portion is higher than an average of concentrations of the another portion. Conversely, that a certain portion has a lower concentration than another portion means that, for example, an average of concentrations of the certain portion is lower than an average of concentrations of the another portion. In the following description, a first conductivity type is an n-type and a second conductivity type is a p-type, but the first conductivity type may be the p-type and the second conductivity type may be the n-type. Note that n⁻ indicates to have a lower impurity concentration than n, and n⁺ indicates that to have a higher impurity concentration than n. Similarly, p⁻ indicates to have a lower impurity concentration than p, and p⁺ indicates to have a higher impurity concentration than p.

### First Preferred Embodiment

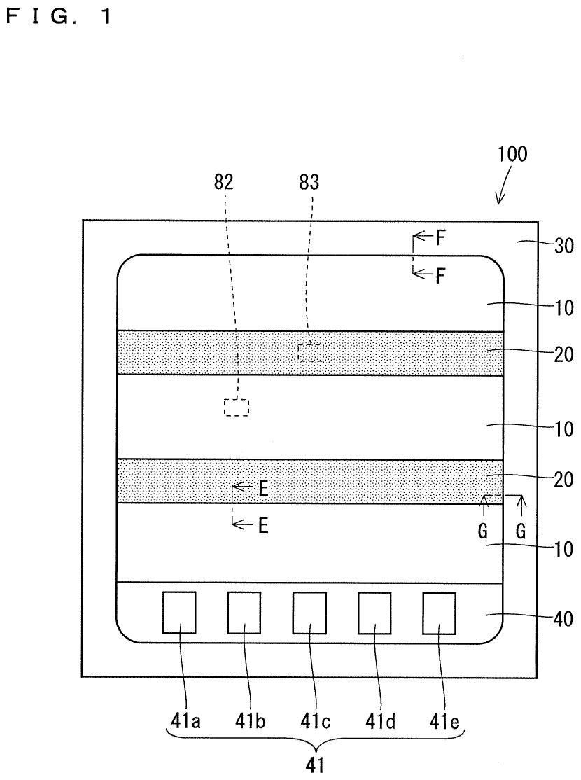

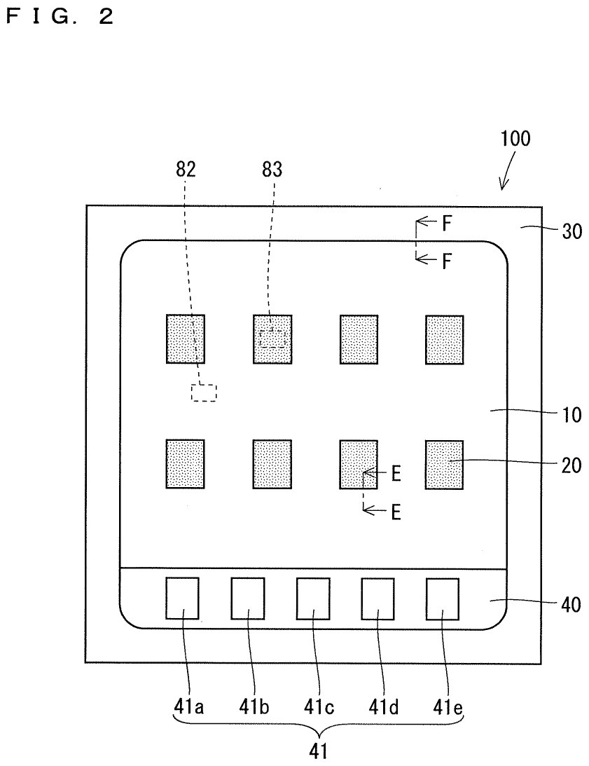

FIG. 1 is a plan view illustrating a semiconductor device that is a reverse conducting IGBT (RC-IGBT). FIG. 2 is a plan view illustrating another configuration of the semiconductor device that is the RC-IGBT according to the first preferred embodiment. A semiconductor device 100 illustrated in FIG. 1 includes an IGBT region 10 and a diode region 20 provided side by side in a stripe shape, and may also be simply referred to as a “stripe type” in the following description. The semiconductor device 100 illustrated in FIG. 2 includes a plurality of the diode regions 20 provided in the vertical direction and the horizontal direction and the IGBT regions 10 provided around the diode regions 20, and may also be simply referred to as an “island type” in the following description.

### <Overall Planar Structure of Stripe Type>

In FIG. 1, the semiconductor device 100 includes the IGBT regions 10 and the diode regions 20 in one semiconductor device. The IGBT region 10 and the diode region 20 extend from one end side to the other end side of the semiconductor device 100, and are alternately provided in a stripe shape in a direction orthogonal to extending directions of the IGBT region 10 and the diode region 20. FIG. 1 illustrates three IGBT regions 10 and two diode regions 20 and illustrates a configuration in which all the diode regions 20 are each sandwiched between the IGBT regions 10. However, the number of the IGBT regions 10 and the number of the diode regions 20 are not limited thereto, and the number of the IGBT regions 10 may be three or more or may be three or less, and the number of the diode regions 20 may be two or more or may be two or less. In addition, locations of the IGBT region 10 and the diode region 20 in FIG. 1 may be interchanged, or all the IGBT regions 10 may be each sandwiched between the diode regions 20. In addition, one IGBT region 10 and one diode region 20 may be provided adjacent to each other.

As illustrated in FIG. 1, a pad region 40 is provided adjacent to the IGBT region 10 on the lower side on the paper surface. The pad region 40 is a region where a control pad 41 for controlling the semiconductor device 100 is provided. In the following description, the IGBT regions 10 and the diode regions 20 may be collectively referred to as a cell region. A termination region 30 is provided around a combined region of the cell region and the pad region 40 in order to hold a withstand voltage of the semiconductor device 100. A known withstand voltage holding structure may be appropriately provided in the termination region 30. In the withstand voltage holding structure, for example, a field limiting ring (FLR) surrounding the cell region with a p-type termination well layer of a p-type semiconductor or variation of lateral doping (VLD) surrounding a cell region with a p-type well layer having a concentration gradient may be provided on a front surface side of the semiconductor device 100. Note that it is sufficient to appropriately select the number of ring-shaped p-type termination well layers used for the FLR and a concentration distribution used for the VLD according to the withstand voltage design of the semiconductor device 100. In addition, a p-type termination well layer may be provided over substantially the entire pad region 40, and an IGBT cell or a diode cell may be provided in the pad region 40.

The control pad 41 includes, for example, at least one of a current sense pad 41a, a Kelvin emitter pad 41b, a gate pad 41c, and temperature sense diode pads 41d and 41e. In the present specification, for example, at least one of A, B, C, . . . , and Z means any one of all combinations extracted from one or more groups of A, B, C, . . . , and Z.

The current sense pad 41a is a control pad for detecting a current flowing through the cell region of the semiconductor device 100. The current sense pad 41a is electrically connected to the cell region such that, when a current flows through the cell region of the semiconductor device 100, a current of a fraction to several ten-thousandths of the current flowing through the entire cell region flows through part of the IGBT cell or the diode cell in the cell region.

The Kelvin emitter pad 41b and the gate pad 41c are control pads to which a gate drive voltage for controlling on and off of the semiconductor device 100 is applied. The Kelvin emitter pad 41b is electrically connected to a p-type base layer of the IGBT cell. The gate pad 41c is electrically connected to a gate trench electrode of the IGBT cell. The Kelvin emitter pad 41b and the p-type base layer may be electrically connected via a p⁺ type contact layer. The temperature sense diode pads 41d and 41e are control pads electrically connected to an anode and a cathode of a temperature sense diode provided in the semiconductor device 100. A voltage between the anode and the cathode of the temperature sense diode (not illustrated) provided in the cell region is measured through the temperature sense diode pads 41d and 41e, and a temperature of the semiconductor device 100 is measured on the basis of the voltage.

### <Overall Planar Structure of Island Type>

In FIG. 2, the semiconductor device 100 includes the IGBT region 10 and the diode region 20 in one semiconductor device. A plurality of the diode regions 20 are arranged side by side in each of the vertical direction and the horizontal direction in the semiconductor device 100, and the periphery of each of the diode regions 20 is surrounded by the IGBT region 10. That is, the plurality of diode regions 20 are provided in an island shape in the IGBT region 10. FIG. 2 illustrates a configuration in which the diode regions 20 are provided in a matrix of four columns in the left-and-right direction on the paper and two rows in the upper-and-lower direction on the paper surface. However, the number and arrangement of the diode regions 20 are not limited thereto, and it is sufficient to adopt a configuration in which one or a plurality of diode regions 20 are scattered in the IGBT region 10, and the periphery of each of the diode regions 20 is surrounded by the IGBT region 10.

As illustrated in FIG. 2, the pad region 40 is provided adjacent to the lower side of the IGBT region 10 on the paper surface. The pad region 40 is a region where a control pad 41 for controlling the semiconductor device 100 is provided. Also in this description, the IGBT region 10 and the diode region 20 are collectively referred to as the cell region. A termination region 30 is provided around a combined region of the cell region and the pad region 40 in order to hold a withstand voltage of the semiconductor device 100. A known withstand voltage holding structure may be appropriately provided in the termination region 30. In the withstand voltage holding structure, for example, an FLR surrounding the combined region of the cell region and the pad region 40 with a p-type termination well layer of a p-type semiconductor or a VLD surrounding the cell region with a p-type well layer having a concentration gradient may be provided on the front surface side of the semiconductor device 100. Note that it is sufficient to appropriately select the number of ring-shaped p-type termination well layers used for the FLR and a concentration distribution used for the VLD according to the withstand voltage design of the semiconductor device 100. In addition, a p-type termination well layer may be provided over substantially the entire pad region 40, and an IGBT cell or a diode cell may be provided in the pad region 40.

The control pad 41 includes, for example, at least one of a current sense pad 41a, a Kelvin emitter pad 41b, a gate pad 41c, and temperature sense diode pads 41d and 41e.

The current sense pad 41a is a control pad for detecting a current flowing through the cell region of the semiconductor device 100. The current sense pad 41a is electrically connected to the cell region such that, when a current flows through the cell region of the semiconductor device 100, a current of a fraction to several ten-thousandths of the current flowing through the entire cell region flows through part of the IGBT cell or the diode cell in the cell region.

The Kelvin emitter pad 41b and the gate pad 41c are control pads to which a gate drive voltage for controlling on and off of the semiconductor device 100 is applied. The Kelvin emitter pad 41b is electrically connected to a p-type base layer and an n⁺ type source layer of the IGBT cell. The gate pad 41c is electrically connected to a gate trench electrode of the IGBT cell. The Kelvin emitter pad 41b and the p-type base layer may be electrically connected via a p⁺ type contact layer. The temperature sense diode pads 41d and 41e are control pads electrically connected to an anode and a cathode of a temperature sense diode provided in the semiconductor device 100. A voltage between the anode and the cathode of the temperature sense diode (not illustrated) provided in the cell region is measured through the temperature sense diode pads 41d and 41e, and a temperature of the semiconductor device 100 is measured on the basis of the voltage.

### <IGBT Region 10>

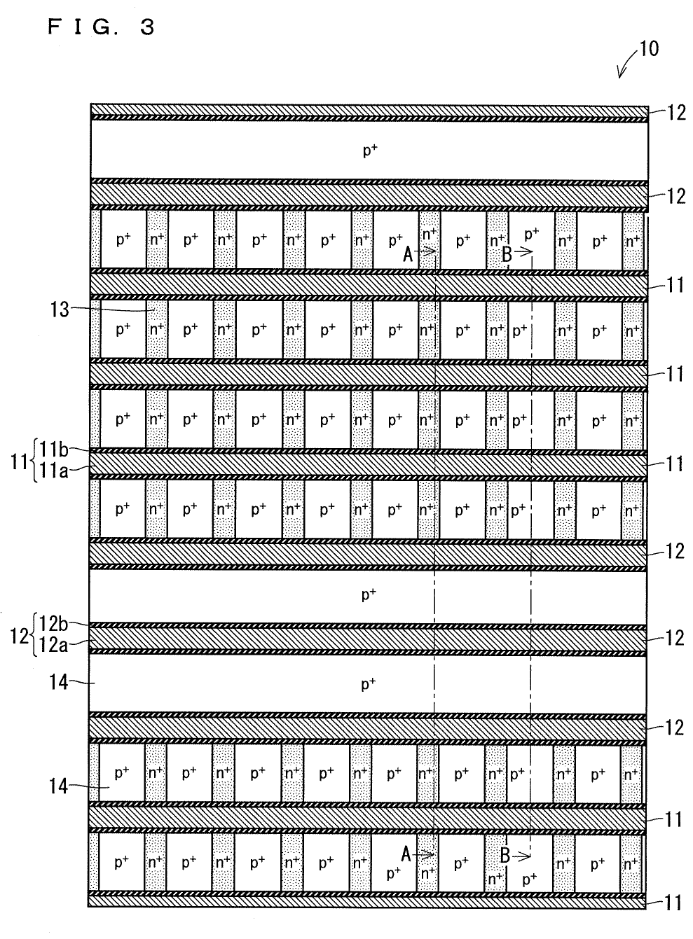

FIG. 3 is a partially enlarged plan view illustrating a configuration of the IGBT region 10 of a semiconductor device that is an RC-IGBT. Specifically, FIG. 3 is an enlarged view of a region surrounded by a broken line 82 in the semiconductor device 100 illustrated in FIGS. 1 and 2.

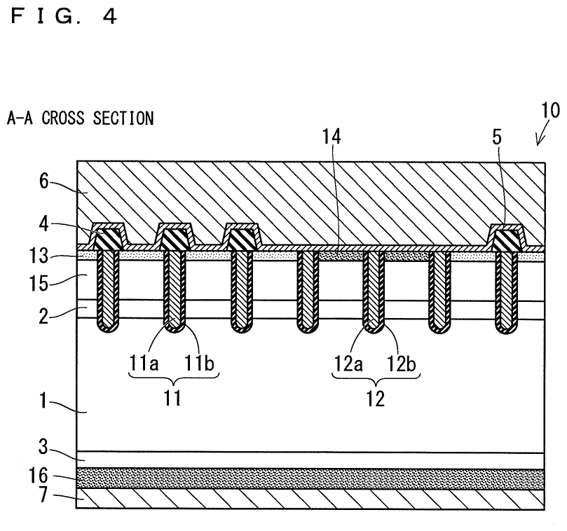

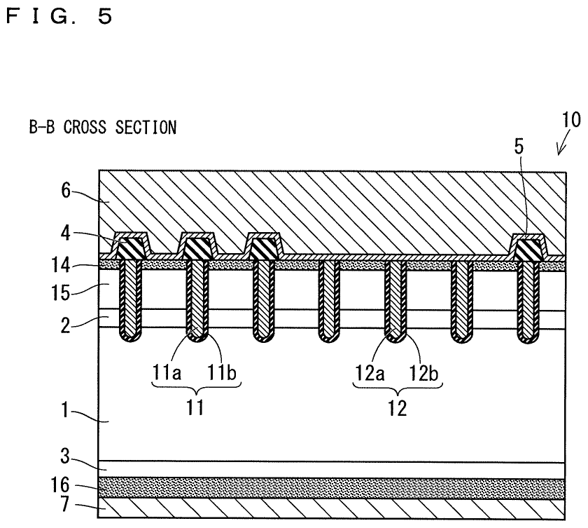

FIGS. 4 and 5 are cross-sectional views each illustrating a configuration of the IGBT region 10 of the semiconductor device that is the RC-IGBT. Specifically, FIG. 4 is a cross-sectional view of the semiconductor device 100 illustrated in FIG. 3 taken along an alternate long and short dash line A-A, and FIG. 5 is a cross-sectional view of the semiconductor device 100 illustrated in FIG. 3 taken along an alternate long and short dash line B-B.

As illustrated in FIG. 3, the IGBT region 10 includes an active trench gate 11 and a dummy trench gate 12 provided in a stripe shape. In the semiconductor device 100 of FIG. 1, the active trench gate 11 and the dummy trench gate 12 extend in a longitudinal direction of the IGBT region 10, and the longitudinal direction of the IGBT region 10 corresponds to longitudinal directions of the active trench gate 11 and the dummy trench gate 12. On the other hand, in the semiconductor device 100 of FIG. 2, there is no particular distinction between the longitudinal direction and a lateral direction in the IGBT region 10, the left-right direction on the paper surface may correspond to the longitudinal directions of the active trench gate 11 and the dummy trench gate 12, and the upper-and-lower direction on the paper surface may correspond to the longitudinal directions of the active trench gate 11 and the dummy trench gate 12.

The active trench gate 11 has a configuration in which a gate trench electrode 11a is provided in a trench of a semiconductor substrate with a gate trench insulating film 11b interposed therebetween. The dummy trench gate 12 has a configuration in which a dummy trench electrode 12a is provided in a trench of the semiconductor substrate with a dummy trench insulating film 12b interposed therebetween. The gate trench electrode 11a of the active trench gate 11 is electrically connected to the gate pad 41c in FIGS. 1 and 2. The dummy trench electrode 12a of the dummy trench gate 12 is electrically connected to an emitter electrode provided on a front surface of the semiconductor device 100.

As illustrated in FIG. 3, an n⁺ type source layer 13 is provided on both sides in a width direction of the active trench gate 11 so as to be in contact with the gate trench insulating film 11b. The n⁺ type source layer 13 is also called an n⁺ type emitter layer depending on a semiconductor device. The n⁺ type source layer 13 is a semiconductor layer containing, for example, arsenic or phosphorus as n-type impurities, and a concentration of the n-type impurities is, for example, 1.0E+17/cm³ to 1.0E+20/cm³. The n⁺ type source layer 13 is provided alternately with a p⁺ type contact layer 14 along an extending direction of the active trench gate 11. In addition, the p⁺ type contact layer 14 is provided between two adjacent dummy trench gates 12 so as to be in contact with the dummy trench insulating film 12b. The p⁺ type contact layer 14 is a semiconductor layer containing, for example, boron or aluminum as p-type impurities, and a concentration of the p-type impurities is, for example, 1.0E+15/cm³ to 1.0E+20/cm³.

As illustrated in FIG. 3, in the IGBT region 10 of the semiconductor device 100, three dummy trench gates 12 are arrayed side by side next to three active trench gates 11 arrayed side by side. Then, three active trench gates 11 different from those described above are arrayed side by side next to the three dummy trench gates 12 arrayed side by side. The IGBT region 10 has a configuration in which a set of the active trench gates 11 and a set of the dummy trench gates 12 are alternately arrayed side by side in this manner. The number of the active trench gates 11 included in one set of the active trench gates 11 is three in FIG. 3, but only needs to be one or more. In addition, the number of the dummy trench gates 12 included in one set of the dummy trench gates 12 may be one or more, and the number of the dummy trench gates 12 may be zero. That is, the entire trench gate provided in the IGBT region 10 may be the active trench gate 11.

FIG. 4 is the cross-sectional view of the semiconductor device 100 taken along the alternate long and short dash line A-A in FIG. 3, and is a cross-sectional view of the IGBT region 10. The semiconductor device 100 includes an n⁻ type drift layer 1 included in the semiconductor substrate. The n⁻ type drift layer 1 is a semiconductor layer containing, for example, arsenic or phosphorus as n-type impurities, and a concentration of the n-type impurities is, for example, 1.0E+12/cm³ to 1.0E+15/cm³. Note that the concentration of the n-type impurities in the n⁺ type source layer 13 described above is higher than the concentration of the n-type impurities in the n⁻ type drift layer 1.

In FIG. 4, a range of the semiconductor substrate is a range from the n⁺ type source layer 13 and the p⁺ type contact layer 14 to a p-type collector layer 16. The p-type collector layer 16 is also called a p-type drain layer depending on a semiconductor device. In FIG. 4, upper ends of the n⁺ type source layer 13 and the p⁺ type contact layer 14 on the paper surface are referred to as a front surface of the semiconductor substrate, and a lower end of the p-type collector layer 16 is referred to as a back surface of the semiconductor substrate. The semiconductor device 100 includes the n⁻ type drift layer 1 between the front surface and the back surface opposite to the front surface in the IGBT region 10 of the cell region. Note that the semiconductor substrate may include, for example, at least one of a wafer and an epitaxial growth layer. In addition, the semiconductor substrate may include a wide band gap semiconductor (silicon carbide (SiC), gallium nitride (GaN), or diamond) capable of stable operation at a high temperature.

As illustrated in FIG. 4, an n-type carrier accumulation layer 2 having a higher concentration of n-type impurities than the n⁻ type drift layer 1 is provided on the front surface side of the n type drift layer 1 in the IGBT region 10. The n-type carrier accumulation layer 2 is a semiconductor layer containing, for example, arsenic or phosphorus as the n-type impurities, and the concentration of the n-type impurities is, for example, 1.0E+13/cm³ to 1.0E+17/cm³. Note that the semiconductor device 100 may have a configuration in which the n-type carrier accumulation layer 2 is not provided and the n⁻ type drift layer 1 is also provided in a region of the n-type carrier accumulation layer 2 illustrated in FIG. 4. Since the n-type carrier accumulation layer 2 is provided, conduction loss when a current flows through the IGBT region 10 can be reduced. The n-type carrier accumulation layer 2 and the n⁻ type drift layer 1 may be collectively referred to as a drift layer.

The n-type carrier accumulation layer 2 is formed by ion-implanting the n-type impurities into the semiconductor substrate forming the n⁻ type drift layer 1, and then diffusing the implanted n-type impurities into the semiconductor substrate, which is the n-type drift layer 1, by annealing.

A p-type base layer 15 is provided on the front surface side of the n-type carrier accumulation layer 2. The p-type base layer 15 is selectively and indirectly provided on the n⁻ type drift layer 1 due to the n-type carrier accumulation layer 2 in the example of FIG. 4, but may be selectively and directly provided on the n⁻ type drift layer 1. The p-type base layer 15 is a semiconductor layer containing, for example, boron or aluminum as p-type impurities, and a concentration of the p-type impurities is, for example, 1.0E+12/cm³ to 1.0E+19/cm³. The p-type base layer 15 is in contact with the gate trench insulating film 11b of the active trench gate 11. In the example of FIG. 4, the p-type base layer 15 is also in contact with the dummy trench insulating film 12b of the dummy trench gate 12.

The n⁺ type source layer 13 in contact with the gate trench insulating film 11b of the active trench gate 11 is selectively provided in a partial region on the front surface side of the p-type base layer 15, and the p⁺ type contact layer 14 is selectively provided in the remaining region on the front surface side of the p-type base layer 15. The n⁺ type source layer 13 and the p⁺ type contact layer 14 form the front surface of the semiconductor substrate. Note that the p⁺ type contact layer 14 is a region having a higher p-type impurity concentration than the p-type base layer 15. The p⁺ type contact layer 14 and the p-type base layer 15 may be referred to individually when the both need to be distinguished from each other, and the p⁺ type contact layer 14 and the p-type base layer 15 may be collectively referred to as a p-type base layer when the both do not need to be distinguished from each other.

In addition, an n-type buffer layer 3 having a higher n-type impurity concentration than the n⁻ type drift layer 1 is provided on a back surface side of the n⁻ type drift layer 1 of the semiconductor device 100. The n-type buffer layer 3 is provided to suppress punch-through of a depletion layer extending from the p-type base layer 15 to the back surface side when the semiconductor device 100 is in an off state. The n-type buffer layer 3 may be formed by, for example, implanting phosphorus (P) or protons (H⁺), or may be formed by implanting both phosphorus (P) and protons (H⁺). The concentration of the n-type impurities of the n-type buffer layer 3 is, for example, 1.0E+12/cm³ to 1.0E+18/cm³. Note that the semiconductor device 100 may have a configuration in which the n-type buffer layer 3 is not provided and the n⁻ type drift layer 1 is provided in a region of the n-type buffer layer 3 illustrated in FIG. 4. The n-type buffer layer 3 and the n type drift layer 1 may be collectively referred to as a drift layer.

The p-type collector layer 16 is provided on the back surface side of the n-type buffer layer 3 of the semiconductor device 100. That is, the p-type collector layer 16 is provided between the n⁻ type drift layer 1 and the back surface. The p-type collector layer 16 is a semiconductor layer containing, for example, boron or aluminum as p-type impurities, and a concentration of the p-type impurities is, for example, 1.0E+16/cm³ to 1.0E+20/cm³. The p-type collector layer 16 forms the back surface of the semiconductor substrate. The p-type collector layer 16 may be provided not only in the IGBT region 10 but also in the termination region 30 as a p-type termination collector layer 16a described later. In addition, the p-type collector layer 16 may be provided to partially protrude from the IGBT region 10 to the diode region 20.

As illustrated in FIG. 4, trenches, which penetrate the p-type base layer 15 from the front surface of the semiconductor substrate and reach the n⁻ type drift layer 1, are provided in the IGBT region 10 of the semiconductor device 100. The gate trench electrodes 11a are provided in some trenches with the gate trench insulating films 11b interposed therebetween to form the active trench gates 11, respectively. The gate trench electrodes 11a face the n⁻ type drift layer 1 via the gate trench insulating films 11b. In addition, the dummy trench electrodes 12a are provided in some trenches with the dummy trench insulating films 12b interposed therebetween to form the dummy trench gates 12, respectively. The dummy trench electrodes 12a face the n⁻ type drift layer 1 via the dummy trench insulating films 12b.

The gate trench insulating film 11b of the active trench gate 11 is in contact with the p-type base layer 15 and the n⁺ type source layer 13. When the gate drive voltage is applied to the gate trench electrode 11a, a channel is formed in the p-type base layer 15 in contact with the gate trench insulating film 11b of the active trench gate 11.

As illustrated in FIG. 4, an interlayer insulating film 4 is provided on the gate trench electrode 11a of the active trench gate 11. A barrier metal 5 is provided on a region of the front surface of the semiconductor substrate where the interlayer insulating film 4 is not provided and on the interlayer insulating film 4. The barrier metal 5 may be, for example, a conductor containing titanium (Ti), and specifically, may be titanium nitride or TiSi obtained by alloying titanium and silicon (Si). As illustrated in FIG. 4, the barrier metal 5 is in ohmic contact with the n⁺ type source layer 13, the p⁺ type contact layer 14, and the dummy trench electrode 12a, and is electrically connected to the n⁺ type source layer 13, the p⁺ type contact layer 14, and the dummy trench electrode 12a. On the other hand, the barrier metal 5 is electrically insulated from the gate trench electrode 11a by the interlayer insulating film 4.

An emitter electrode 6 that is an electrode containing aluminum is provided on the barrier metal 5. The emitter electrode 6 may be made of, for example, an aluminum alloy such as an aluminum silicon alloy (Al—Si-based alloy), or may be an electrode including a plurality of layers of metal films in which a plating film is formed on an electrode made of an aluminum alloy by electroless plating or electrolytic plating. The plating film formed by electroless plating or electrolytic plating may be, for example, a nickel (Ni) plating film. Note that the emitter electrode 6 may be provided on the n⁺ type source layer 13, the p⁺ type contact layer 14, and the dummy trench electrode 12a without providing the barrier metal 5. In addition, the barrier metal 5 may be provided only on an n-type semiconductor layer such as the n⁺ type source layer 13. The barrier metal 5 and the emitter electrode 6 may be collectively referred to as an emitter electrode.

Although FIG. 4 illustrates the configuration in which the interlayer insulating film 4 is not provided on the dummy trench electrode 12a of the dummy trench gate 12, the interlayer insulating film 4 may be provided on the dummy trench electrode 12a of the dummy trench gate 12 in a cross-sectional portion of FIG. 4. It is sufficient that the emitter electrode 6 and the dummy trench electrode 12a are electrically connected in another cross-sectional portion in a case where the interlayer insulating film 4 is provided on the dummy trench electrode 12a of the dummy trench gate 12 in the cross-sectional portion of FIG. 4.

The collector electrode 7 is provided on the back surface side of the p-type collector layer 16. The collector electrode 7 may be formed of an aluminum alloy or a plurality of layers of an aluminum alloy and a plating film, which is similar to the emitter electrode 6. The collector electrode 7 may have a configuration different from that of the emitter electrode 6. The collector electrode 7 is in ohmic contact with the p-type collector layer 16 and is electrically connected to the p-type collector layer 16.

FIG. 5 is the cross-sectional view of the semiconductor device 100 taken along the alternate long and short dash line B-B in FIG. 3, and is a cross-sectional view of the IGBT region 10. Unlike the cross-sectional portion along the alternate long and short dash line A-A illustrated in FIG. 4, a cross-sectional portion along the alternate long and short dash line B-B in FIG. 5 does not include the n⁺ type source layer 13 being in contact with the active trench gate 11 and provided on the front surface side of the semiconductor substrate. That is, the n⁺ type source layer 13 illustrated in FIG. 3 is selectively provided on the front surface side of a p-type base layer. Note that the p-type base layer referred to here may include the p-type base layer 15 and the p⁺ type contact layer 14.

### <Diode Region 20>

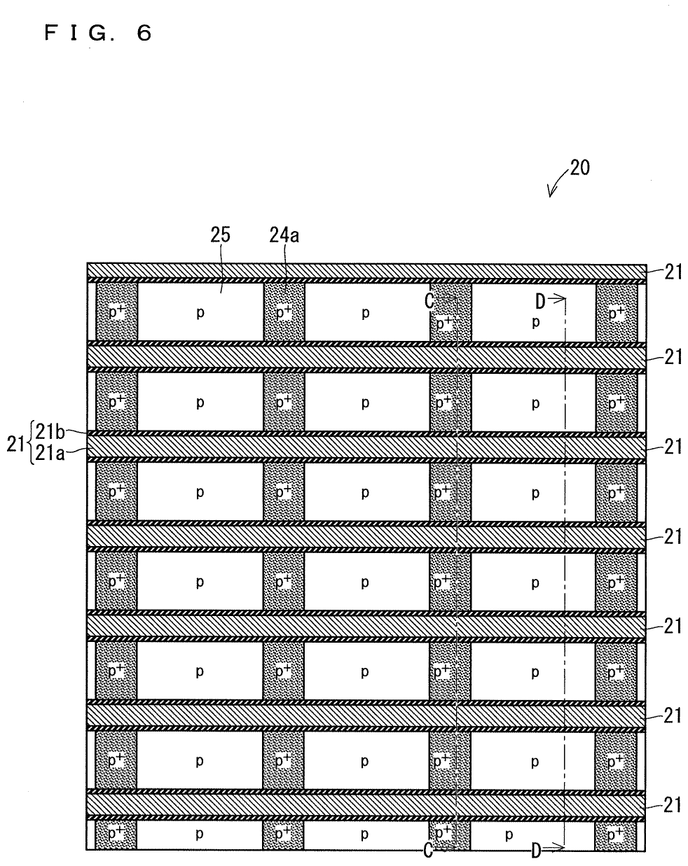

FIG. 6 is a partially enlarged plan view illustrating a configuration of the diode region 20 of a semiconductor device that is an RC-IGBT. Specifically, FIG. 6 is an enlarged view of a region surrounded by a broken line 83 in the semiconductor device 100 illustrated in FIGS. 1 and 2.

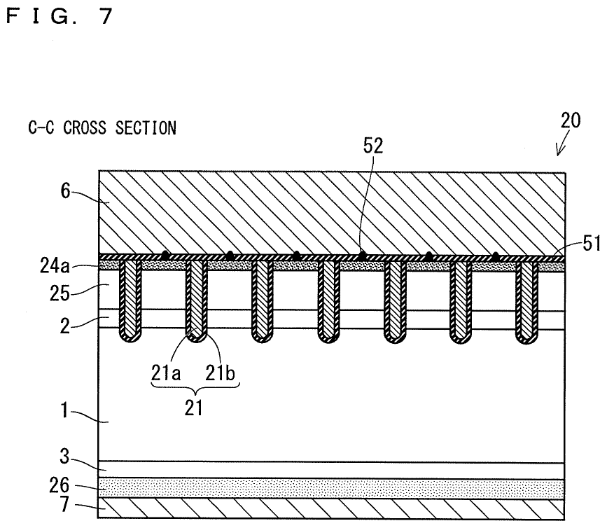

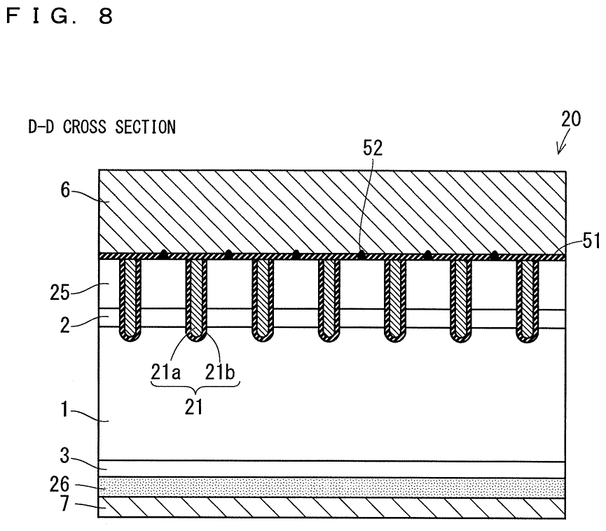

FIGS. 7 and 8 are cross-sectional views each illustrating the configuration of the diode region 20 of the semiconductor device that is the RC-IGBT. Specifically, FIG. 7 is a cross-sectional view of the semiconductor device 100 illustrated in FIG. 6 taken along an alternate long and short dash line C-C, and FIG. 8 is a cross-sectional view of the semiconductor device 100 illustrated in FIG. 6 taken along an alternate long and short dash line D-D.

A diode trench gate 21 extends from one end side of the diode region 20 of the cell region toward the opposite end side along the front surface of the semiconductor device 100. The diode trench gate 21 is configured by providing a diode trench electrode 21a in a trench of the diode region 20 with a diode trench insulating film 21b interposed therebetween. The diode trench electrode 21a faces the n⁻ type drift layer 1 via the diode trench insulating film 21b.

A p⁺ type contact layer 24a and a p-type anode layer 25 having a lower p-type impurity concentration than the p⁺ type contact layer 24a are provided between two adjacent diode trench gates 21. The p⁺ type contact layer 24a is a semiconductor layer containing, for example, boron or aluminum as p-type impurities, and a concentration of the p-type impurities is, for example, 1.0E+15/cm³ to 1.0E+20/cm³. The p-type anode layer 25 is a semiconductor layer containing, for example, boron or aluminum as p-type impurities, and a concentration of the p-type impurities is, for example, 1.0E+12/cm³ to 1.0E+19/cm³. The p⁺ type contact layer 24a and the p-type anode layer 25 are alternately provided in a longitudinal direction of the diode trench gate 21.

FIG. 7 is the cross-sectional view of the semiconductor device 100 taken along the alternate long and short dash line C-C in FIG. 6, and is a cross-sectional view of the diode region 20. The semiconductor device 100 also includes the n⁻ type drift layer 1 included in a semiconductor substrate in the diode region 20 as in the IGBT region 10. The n⁻ type drift layer 1 in the diode region 20 and the n⁻ type drift layer 1 in the IGBT region 10 are formed continuously and integrally, and are formed of the same semiconductor substrate.

In FIG. 7, a range of the semiconductor substrate is a range from the p⁺ type contact layer 24a to an n⁺ type cathode layer 26. In FIG. 7, an upper end of the p⁺ type contact layer 24a on the paper surface is referred to as a front surface of the semiconductor substrate, and a lower end of the n⁺ type cathode layer 26 on the paper surface is referred to as a back surface of the semiconductor substrate. The front surface of the diode region 20 and the front surface of the IGBT region 10 are included in the same plane, and the back surface of the diode region 20 and the back surface of the IGBT region 10 are included in the same plane.

As illustrated in FIG. 7, also in the diode region 20, the n-type carrier accumulation layer 2 is provided on the front surface side of the n⁻ type drift layer 1, and the n-type buffer layer 3 is provided on the back surface side of the n⁻ type drift layer 1 as in the IGBT region 10. The n-type carrier accumulation layer 2 and the n-type buffer layer 3 provided in the diode region 20 may have the same configurations as the n-type carrier accumulation layer 2 and the n-type buffer layer 3 provided in the IGBT region 10. Note that the n-type carrier accumulation layer 2 is not necessarily provided in the IGBT region 10 and the diode region 20, and for example, a configuration in which the n-type carrier accumulation layer 2 is provided in the IGBT region 10 but is not provided in the diode region 20 may be adopted. In addition, the n type drift layer 1, the n-type carrier accumulation layer 2, and the n-type buffer layer 3 may be collectively referred to as a drift layer as in the IGBT region 10.

The p-type anode layer 25 is provided on the front surface side of the n-type carrier accumulation layer 2. The p-type anode layer 25 is selectively and indirectly provided on the n⁻ type drift layer 1 due to the n-type carrier accumulation layer 2 in the example of FIG. 7, but may be selectively and directly provided on the n type drift layer 1. The p-type anode layer 25 is provided between the n type drift layer 1 and the front surface. The p-type anode layer 25 and the p-type base layer 15 may be simultaneously formed by making the concentration of the p-type impurities of the p-type anode layer 25 the same as the concentration of the p-type impurities of the p-type base layer 15 of the IGBT region 10. In addition, the p-type impurity concentration of the p-type anode layer 25 may be lower than the p-type impurity concentration of the p-type base layer 15 of the IGBT region 10 so as to reduce the amount of holes implanted into the diode region 20 during diode operation. Since the amount of holes implanted during the diode operation is reduced, recovery loss during the diode operation can be reduced.

The p⁺ type contact layer 24a as a first contact layer is provided on the front surface side of the p-type anode layer 25. The p⁺ type contact layer 24a is provided on at least a part of the p-type anode layer 25. The p-type impurity concentration of the p⁺ type contact layer 24a may be the same as or different from the p-type impurity concentration of the p⁺ type contact layer 14 of the IGBT region 10. The p⁺ type contact layer 24a forms the front surface of the semiconductor substrate. Note that the p⁺ type contact layer 24a is a region having a higher p-type impurity concentration than the p-type anode layer 25, and the p⁺ type contact layer 24a and the p-type anode layer 25 may be referred to individually when the both need to be distinguished from each other, and the p⁺ type contact layer 24a and the p-type anode layer 25 may be collectively referred to as a p-type anode layer when the both do not need to be distinguished from each other.

The n⁺ type cathode layer 26 is provided on the back surface side of the n-type buffer layer 3 of the semiconductor device 100. That is, the n⁺ type cathode layer 26 is provided between the n⁻ type drift layer 1 and the back surface. The n⁺ type cathode layer 26 is a semiconductor layer containing, for example, arsenic or phosphorus as n-type impurities, and a concentration of the n-type impurities is, for example, 1.0E+16/cm³ to 1.0E+21/cm³. The n⁺ type cathode layer 26 is provided in a part or a whole of the diode region 20. The n⁺ type cathode layer 26 forms the back surface of the semiconductor substrate. Although not illustrated, a p-type cathode layer that is a p-type semiconductor may be provided by further implanting p-type impurities selectively into a part of a region where the n⁺ type cathode layer 26 is formed.

As illustrated in FIG. 7, trenches, which penetrate the p-type anode layer 25 from the front surface of the semiconductor substrate and reach the n⁻ type drift layer 1, are provided in the diode region 20 of the semiconductor device 100. The diode trench electrodes 21a are provided the trenches of the diode region 20 with the diode trench insulating films 21b interposed therebetween to form the diode trench gates 21, respectively. The diode trench electrode 21a faces the n⁻ type drift layer 1 via the diode trench insulating film 21b.

As illustrated in FIG. 7, a first silicon nodule 52 containing oxygen is provided between the p-type anode layer 25 and the emitter electrode 6. In the example of FIG. 7, the first silicon nodule 52 is provided in contact with the p⁺ type contact layer 24a and the emitter electrode 6. In addition, a silicon layer 51 containing oxygen is provided between the p-type anode layer 25 and the emitter electrode 6, and is provided on the diode trench electrode 21a and the p⁺ type contact layer 24a in the example of FIG. 7. The first silicon nodule 52 penetrates the silicon layer 51 in a thickness direction of the silicon layer 51 and protrudes to the emitter electrode 6.

The emitter electrode 6 is provided above the p-type anode layer 25 and on the silicon layer 51. The emitter electrode 6 provided in the diode region 20 is formed continuously with the emitter electrode 6 provided in the IGBT region 10. Note that the diode trench electrode 21a and the p⁺ type contact layer 24a may be brought into ohmic contact with the emitter electrode 6 without providing the silicon layer 51.

Although FIG. 7 illustrates the configuration in which the interlayer insulating film 4 as in FIG. 4 is not provided on the diode trench electrode 21a of the diode trench gate 21, the interlayer insulating film 4 may be provided on the diode trench electrode 21a in a cross-sectional portion of FIG. 7. It is sufficient that the emitter electrode 6 and the diode trench electrode 21a are electrically connected in another cross-sectional portion in a case where the interlayer insulating film 4 is provided on the diode trench electrode 21a of the diode trench gate 21 in the cross-sectional portion of FIG. 7.

The collector electrode 7 is provided on the back surface side of the n⁺ type cathode layer 26. The collector electrode 7 of the diode region 20 is formed continuously with the collector electrode 7 provided in the IGBT region 10, which is similar to the emitter electrode 6. The collector electrode 7 is in ohmic contact with the n⁺ type cathode layer 26 and is electrically connected to the n⁺ type cathode layer 26.

FIG. 8 is the cross-sectional view of the semiconductor device 100 taken along the alternate long and short dash line D-D in FIG. 6, and is a cross-sectional view of the diode region 20. Unlike the cross-sectional portion along the alternate long and short dash line C-C illustrated in FIG. 7, in a cross-sectional portion along the alternate long and short dash line D-D in FIG. 8, the p⁺ type contact layer 24a is not provided between the p-type anode layer 25 and the silicon layer 51, and the p-type anode layer 25 is the front surface of the semiconductor substrate. That is, the p⁺ type contact layer 24a illustrated in FIG. 7 is selectively provided on the front surface side of the p-type anode layer 25.

### <Configuration of Boundary Region Between IGBT Region 10 and Diode Region 20>

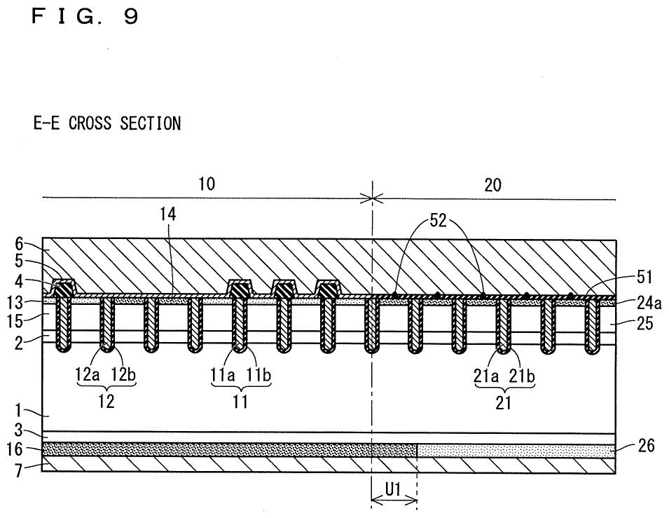

FIG. 9 is a cross-sectional view illustrating a configuration of a boundary region between the IGBT region 10 and the diode region 20 of a semiconductor device that is an RC-IGBT. Specifically, FIG. 9 is a cross-sectional view of the semiconductor device 100 illustrated in FIGS. 1 and 2 taken along an alternate long and short dash line E-E.

As illustrated in FIG. 9, the p-type collector layer 16 provided on the back surface side of the IGBT region 10 and the n⁺ type cathode layer 26 provided on the back surface side of the diode region 20 are adjacent to each other in an in-plane direction of the semiconductor substrate. The p-type collector layer 16 is provided to protrude toward the diode region 20 by a distance U1 from a boundary between the IGBT region 10 and the diode region 20.

Since the p-type collector layer 16 is provided to protrude to the diode region 20 in this manner, a distance between the n⁺ type cathode layer 26 of the diode region 20 and the active trench gate 11 can be increased. For this reason, even in a case where the gate drive voltage is applied to the gate trench electrode 11a during freewheeling diode operation, a current can be suppressed from flowing from the channel formed adjacent to the active trench gate 11 of the IGBT region 10 to the n⁺ type cathode layer 26. The distance U1 may be, for example, 100 μm. Note that the distance U1 may be zero or a distance smaller than 100 μm depending on the application of the semiconductor device 100 that is the RC-IGBT.

As illustrated in FIG. 9, the first silicon nodule 52 and the silicon layer 51 are also provided in the boundary region, and the first silicon nodule 52 penetrates the silicon layer 51 in the thickness direction of the silicon layer 51 and protrudes to the emitter electrode 6.

### <Termination Region 30>

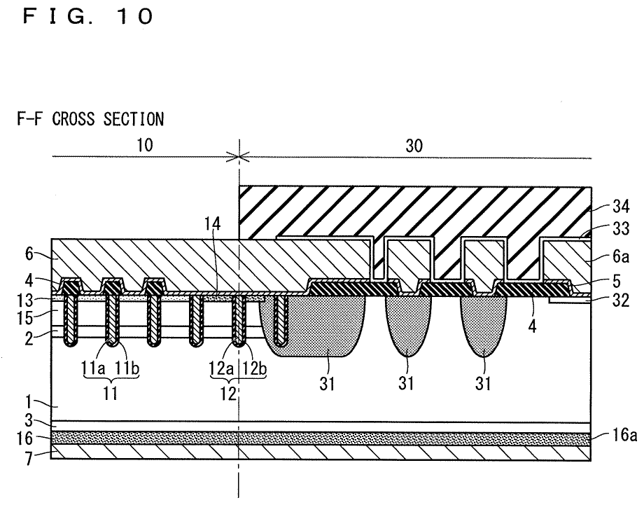

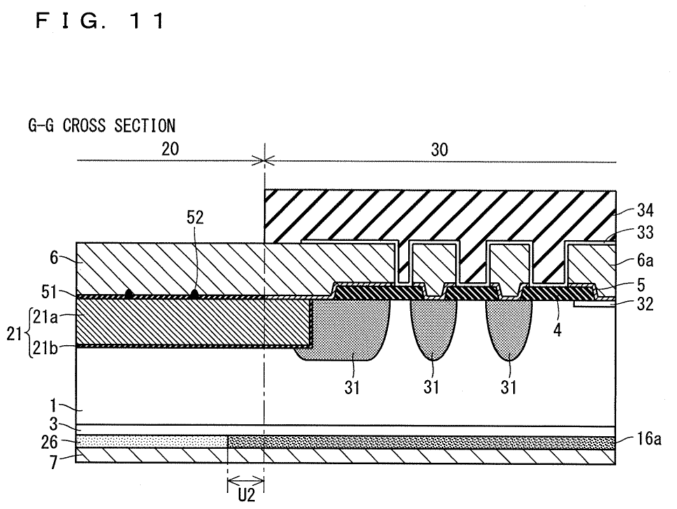

FIGS. 10 and 11 are cross-sectional views each illustrating a configuration of a termination region of the semiconductor device 100 that is the RC-IGBT. Specifically, FIG. 10 is a cross-sectional view taken along an alternate long and short dash line F-F illustrated in FIGS. 1 and 2, and is a cross-sectional view from the IGBT region 10 to the termination region 30. FIG. 11 is a cross-sectional view taken along an alternate long and short dash line G-G in FIG. 1, and is a cross-sectional view from the diode region 20 to the termination region 30.

As illustrated in FIGS. 10 and 11, the termination region 30 of the semiconductor device 100 has the n-type drift layer 1 between a front surface and a back surface of a semiconductor substrate. The front surface and the back surface of the termination region 30 are included in the same plane as the front surface and the back surface of each of the IGBT region 10 and the diode region 20, respectively. In addition, the n type drift layer 1 of the termination region 30 has the same configuration as the n⁻ type drift layers 1 of the IGBT region 10 and the diode region 20, and is formed continuously and integrally with the both.

A p-type termination well layer 31 is selectively provided on the front surface side of the n⁻ type drift layer 1, that is, between the front surface of the semiconductor substrate and the n⁻ type drift layer 1. The p-type termination well layer 31 is a semiconductor layer containing, for example, boron or aluminum as p-type impurities, and a concentration of the p-type impurities is, for example, 1.0E+14/cm³ to 1.0E+19/cm³. The p-type termination well layer 31 is provided to surround the cell region including the IGBT region 10 and the diode region 20. A plurality of the p-type termination well layers 31 are provided in a ring shape, and the number of the provided p-type termination well layers 31 is appropriately selected according to the withstand voltage design of the semiconductor device 100. In addition, an n⁺ type channel stopper layer 32 is provided on the further outer edge side of the p-type termination well layer 31, and the n⁺ type channel stopper layer 32 surrounds the p-type termination well layer 31 in plan view.

The p-type termination collector layer 16a is provided between the n-type drift layer 1 and the back surface of the semiconductor substrate in the termination region 30. The p-type termination collector layer 16a is formed continuously and integrally with the p-type collector layer 16 provided in the IGBT region 10 of the cell region. Therefore, the p-type termination collector layer 16a may also be referred to as a p-type collector layer.

In the configuration in which the diode region 20 is provided adjacent to the termination region 30 as in the semiconductor device 100 illustrated in FIG. 1, the p-type termination collector layer 16a is provided such that an end portion on the diode region 20 side protrudes to the diode region 20 by a distance U2 as illustrated in FIG. 11. According to such a configuration, a distance between the n⁺ type cathode layer 26 and the p-type termination well layer 31 of the diode region 20 can be increased, and thus, it is possible to suppress the p-type termination well layer 31 from operating as an anode of a diode. The distance U2 may be, for example, 100 μm.

On the back surface of the semiconductor substrate, the collector electrode 7 is provided. The collector electrode 7 is integrally formed to be continuous from the cell region including the IGBT region 10 and the diode region 20 to the termination region 30.

On the other hand, on the front surface of the semiconductor substrate in the termination region 30, the emitter electrode 6 continuous from the cell region and a termination electrode 6a, which is structurally separated from the emitter electrode 6, are provided. The emitter electrode 6 and the termination electrode 6a are electrically connected via a semi-insulating film 33. The semi-insulating film 33 may be, for example, semi-insulating silicon nitride (sinSiN). The termination electrode 6a is electrically connected to each of the p-type termination well layer 31 and the n⁺ type channel stopper layer 32 via contact holes of the interlayer insulating film 4 provided on the front surface of the termination region 30. In addition, in the termination region 30, a termination protective film 34 is provided to cover the emitter electrode 6, the termination electrode 6a, and the semi-insulating film 33. The termination protective film 34 is, for example, polyimide.

As illustrated in FIG. 9, the first silicon nodule 52 and the silicon layer 51 are also provided in the boundary region, and the first silicon nodule 52 penetrates the silicon layer 51 in the thickness direction of the silicon layer 51 and protrudes to the emitter electrode 6. Note that the barrier metal 5 is not necessarily provided in the IGBT region 10 or the like as in the diode region 20.

### <Method of Manufacturing RC-IGBT>

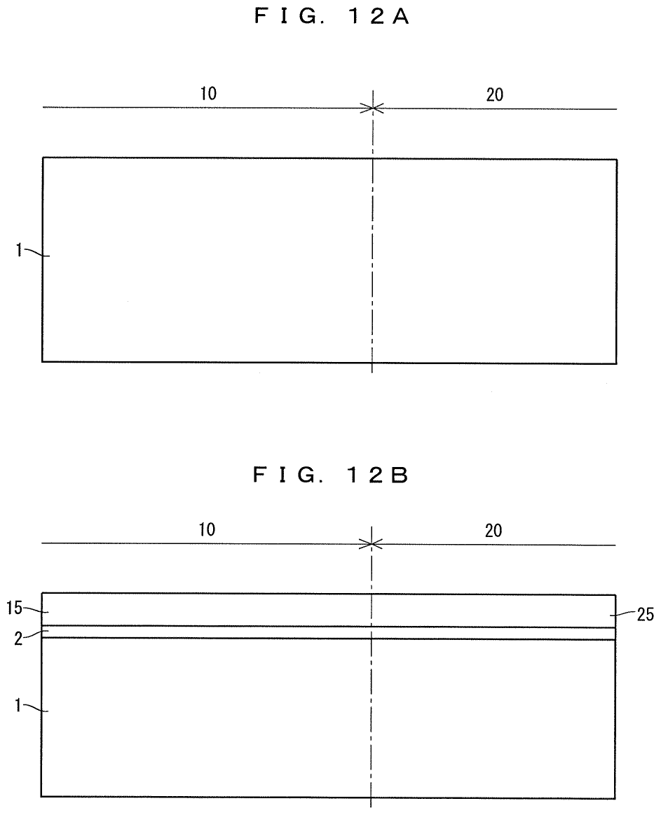

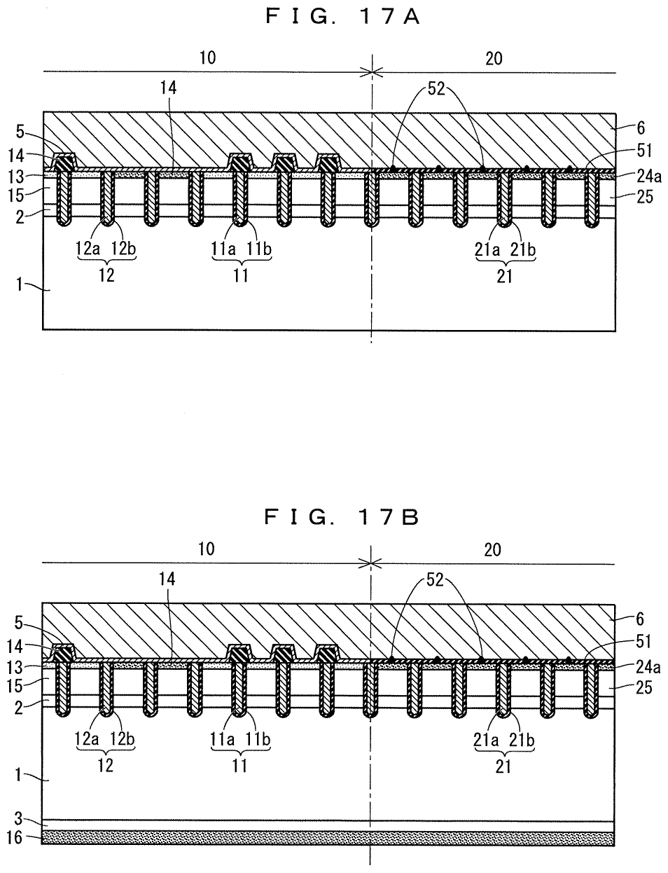

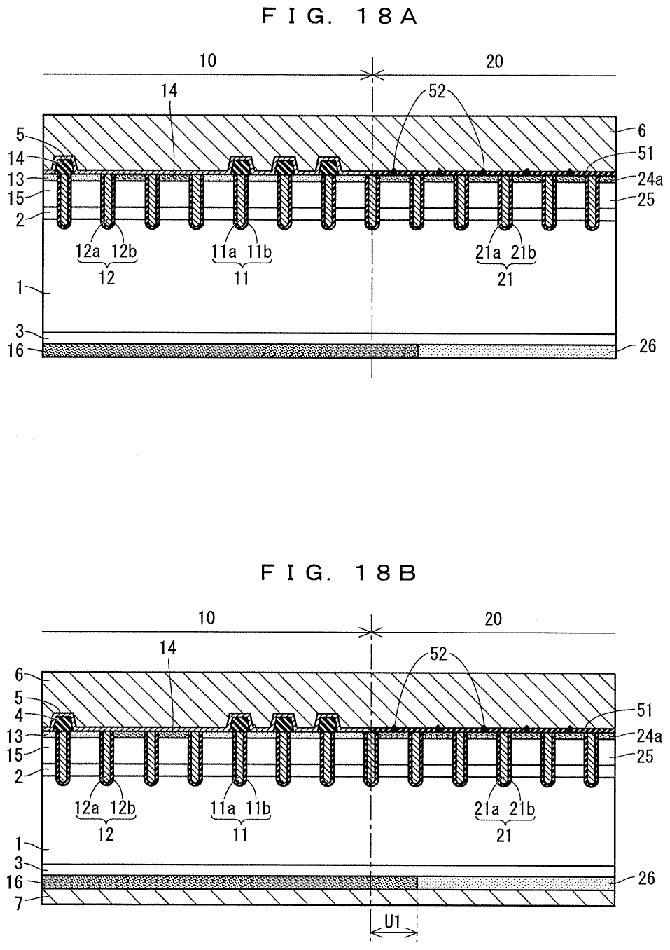

FIGS. 12A to 18B are cross-sectional views each illustrating a method of manufacturing a semiconductor device that is an RC-IGBT. FIGS. 12A to 16B are views illustrating processes of mainly forming a structure of the semiconductor device 100 on the front surface side of the boundary region in FIG. 9, and FIGS. 17A to 18B are views illustrating steps of mainly forming a structure of the semiconductor device 100 on the back surface side of the boundary region in FIG. 9.

First, a semiconductor substrate forming the n-type drift layer 1 is prepared as illustrated in FIG. 12A. The semiconductor substrate may be, for example, a floating zone (FZ) wafer manufactured by an FZ method, a magnetic-field applied CZochralski (MCZ) wafer manufactured by an MCZ method, or an n-type wafer containing n-type impurities. A concentration of the n-type impurities contained in the semiconductor substrate is appropriately selected according to a withstand voltage of a semiconductor device to be manufactured. For example, in a semiconductor device having a withstand voltage of 1200 V, the concentration of n-type impurities is adjusted such that specific resistance of the n-type drift layer 1 forming the semiconductor substrate is about 40 Ω·cm to 120 Ω·cm. As illustrated in FIG. 12A, the entire semiconductor substrate is the n-type drift layer 1 in a process of preparing the semiconductor substrate. P-type or n-type impurity ions are implanted from a front surface side or a back surface side of such a semiconductor substrate and then diffused into the semiconductor substrate by heat treatment or the like to appropriately form p-type or n-type semiconductor layer, whereby the semiconductor device 100 is manufactured.

As illustrated in FIG. 12A, the semiconductor substrate forming the n-type drift layer 1 has a region to be the IGBT region 10 and the diode region 20. Although not illustrated, a region to be the termination region 30 and the like is provided around the region to be the IGBT region 10 and the diode region 20. Although a method of manufacturing configurations of the IGBT region 10 and the diode region 20 of the semiconductor device 100 will be mainly described hereinafter, the termination region 30 and the like of the semiconductor device 100 may be manufactured by a known manufacturing method. For example, in a case where an FLR having the p-type termination well layer 31 as a withstand voltage holding structure is formed in the termination region 30, the FLR may be formed by implanting p-type impurity ions before processing the IGBT region 10 and the diode region 20 of the semiconductor device 100. Alternatively, the FLR may be formed by implanting the p-type impurity ions simultaneously when p-type impurities are ion-implanted into the IGBT region 10 or the diode region 20 of the semiconductor device 100.

Next, as illustrated in FIG. 12B, n-type impurities such as phosphorus (P) are implanted from the front surface side of the semiconductor substrate to form the n-type carrier accumulation layer 2. In addition, p-type impurities such as boron (B) are implanted from the front surface side of the semiconductor substrate to form the p-type base layer 15 and the p-type anode layer 25. The n-type carrier accumulation layer 2, the p-type base layer 15, and the p-type anode layer 25 are formed by implanting impurity ions into the semiconductor substrate and then diffusing the impurity ions by heat treatment. Since the n-type impurities and the p-type impurities are ion-implanted after mask processing is performed on the front surface of the semiconductor substrate, various layers are selectively formed on the front surface side of the semiconductor substrate. The n-type carrier accumulation layer 2, the p-type base layer 15, and the p-type anode layer 25 are formed in the IGBT region 10 and the diode region 20, and are connected to the p-type termination well layer 31 in the termination region 30.

The mask processing is processing of applying a resist on the semiconductor substrate, forming an opening in a predetermined region of the resist using a photolithography technique, and forming a mask on the semiconductor substrate in order to perform the ion implantation or etching on the predetermined region of the semiconductor substrate through the opening. By the mask processing and the ion implantation described above, the n-type carrier accumulation layer 2, the p-type base layer 15, and the p-type anode layer 25 are selectively formed on the front surface side of the IGBT region 10 and the diode region 20. Similarly, the p-type termination well layer 31 is selectively formed in the termination region 30.

The p-type impurities of the p-type base layer 15 and the p-type anode layer 25 may be ion-implanted simultaneously. In this case, the p-type base layer 15 and the p-type anode layer 25 have the same depth and the same p-type impurity concentration. In addition, the p-type impurities of the p-type base layer 15 and the p-type anode layer 25 may be separately ion-implanted by mask processing to make the depth and the p-type impurity concentration different between the p-type base layer 15 and the p-type anode layer 25.

The p-type impurities of the p-type termination well layer 31 and the p-type anode layer 25 of the termination region 30, not illustrated in FIG. 12B, may be simultaneously ion-implanted. In this case, the p-type termination well layer 31 and the p-type anode layer 25 have the same depth and the same p-type impurity concentration. Alternatively, the p-type impurities of the p-type termination well layer 31 and the p-type anode layer 25 may be separately ion-implanted by mask processing to make the depth and the p-type impurity concentration different between the p-type termination well layer 31 and the p-type anode layer 25. Alternatively, the p-type impurities of the p-type termination well layer 31 and the p-type anode layer 25 can also be simultaneously ion-implanted using masks having different aperture ratios such that the p-type impurity concentrations of the p-type termination well layer 31 and the p-type anode layer 25 are different from each other. In this case, it is sufficient to make the aperture ratios of the masks different from each other by using a mesh-like mask as either one or both of the masks.

Similarly, the p-type impurities of the p-type termination well layer 31, the p-type base layer 15, and the p-type anode layer 25 can also be simultaneously ion-implanted using masks having different aperture ratios such that the p-type impurity concentrations of the p-type base layer 15 and the p-type anode layer 25 are different from each other. The p-type termination well layer 31, the p-type base layer 15, and the p-type anode layer 25 may be formed by the ion implantation of the p-type impurities at the same time.

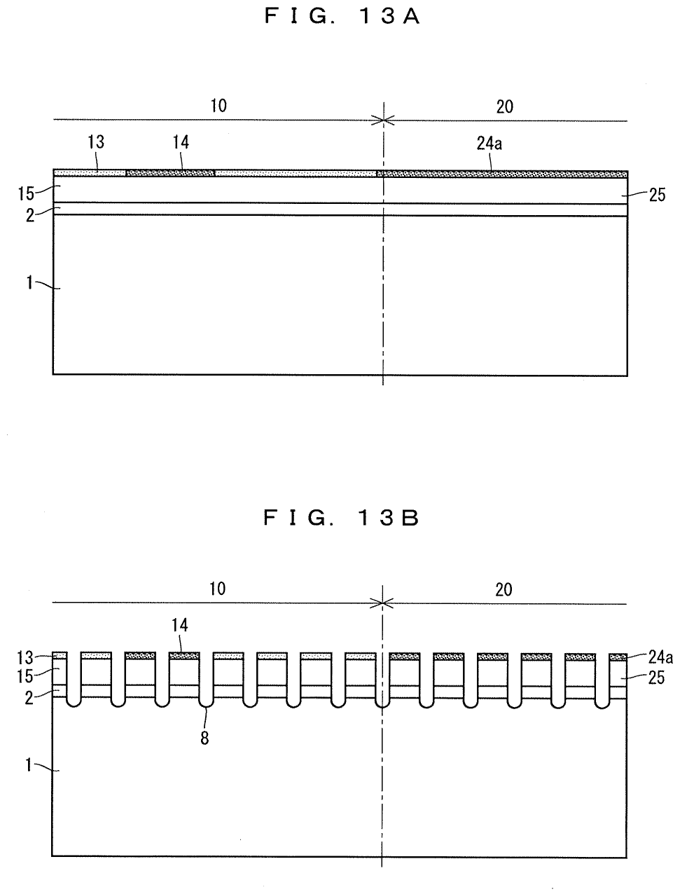

Next, as illustrated in FIG. 13A, the n⁺ type source layer 13 is selectively formed on the front surface side of the p-type base layer 15 in the IGBT region 10 by mask processing and implantation of n-type impurities. The n-type impurities to be implanted may be, for example, arsenic (As) or phosphorus (P). In addition, the p⁺ type contact layer 14 is selectively formed on the front surface side of the p-type base layer 15 of the IGBT region 10, and the p⁺ type contact layer 24a is selectively formed on the front surface side of the p-type anode layer 25 of the diode region 20 by mask processing and implantation of p-type impurities. The p-type impurities to be implanted may be, for example, boron (B), aluminum (Al), or the like.

Next, as illustrated in FIG. 13B, trenches 8, which penetrate the p-type base layer 15 and the p-type anode layer 25 from the front surface side of the semiconductor substrate and reach the n type drift layer 1, are formed. In the IGBT region 10, a sidewall of the trench 8 penetrating the n⁺ type source layer 13 includes a part of the n⁺ type source layer 13. In the IGBT region 10, a sidewall of the trench 8 penetrating the p⁺ type contact layer 14 includes a part of the p⁺ type contact layer 14. In the diode region 20, a sidewall of the trench 8 penetrating the p⁺ type contact layer 24a includes a part of the p⁺ type contact layer 24a.

For example, the trenches 8 are formed by depositing an oxide film such as SiO₂ on the semiconductor substrate, forming openings in the oxide film in portions where the trenches 8 are to be formed by mask processing, and etching the semiconductor substrate using the oxide film having the openings as a mask. In FIG. 13B, the trenches 8 having the same pitch are formed in the IGBT region 10 and the diode region 20, but the trenches 8 may be formed at different pitches between the IGBT region 10 and the diode region 20. The pitches and pattern in plan view of the trenches 8 can be appropriately changed according to a pattern of the mask in the mask processing.

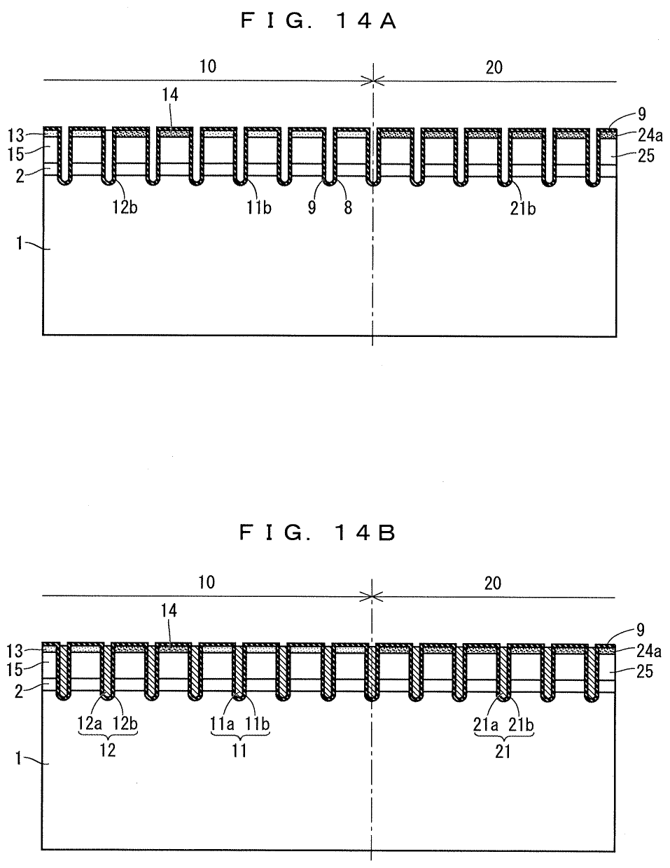

Next, as illustrated in FIG. 14A, the semiconductor substrate is heated in an atmosphere containing oxygen to form an oxide film 9 on inner walls of the trenches 8 and the front surface of the semiconductor substrate. The oxide films 9 formed in the trenches 8 of the IGBT region 10 are the gate trench insulating film 11b of the active trench gate 11 and the dummy trench insulating film 12b of the dummy trench gate 12. The oxide film 9 formed in the trench 8 of the diode region 20 is the diode trench insulating film 21b. The oxide film 9 formed on the front surface of the semiconductor substrate is removed in a later process except for portions formed in the trenches 8.

Next, as illustrated in FIG. 14B, polysilicon doped with n-type or p-type impurities by chemical vapor deposition (CVD) or the like is deposited on the oxide films 9 in the trenches 8 to form the gate trench electrode 11a, the dummy trench electrode 12a, and the diode trench electrode 21a.

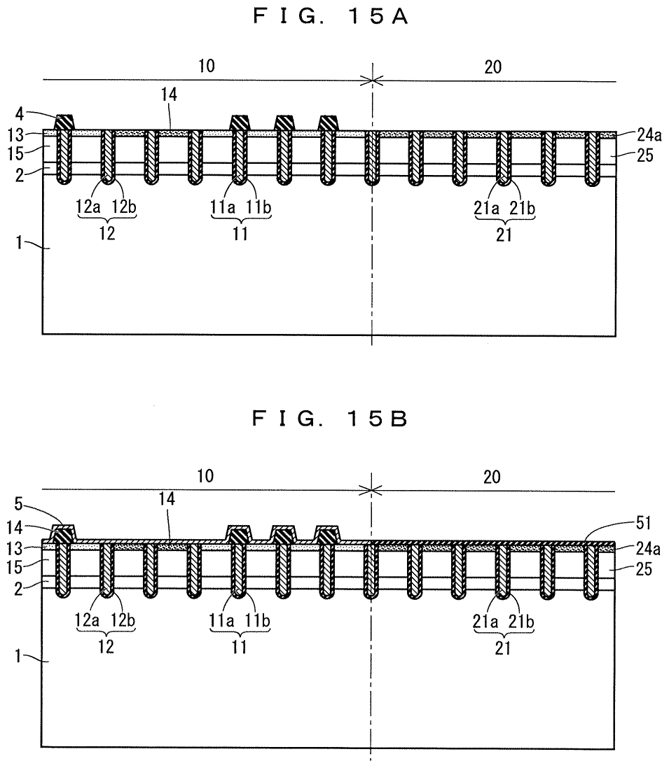

Next, as illustrated in FIG. 15A, the interlayer insulating film 4 is formed on the gate trench electrode 11a of the active trench gate 11 of the IGBT region 10. The interlayer insulating film 4 may be, for example, SiO₂. Formation of contact holes in a deposited insulating film to be the interlayer insulating film 4 and the removal of the oxide film 9 formed on the front surface of the semiconductor substrate are performed by mask processing to form the interlayer insulating film 4 and the like in FIG. 15A. The contact holes of the interlayer insulating film 4 are formed on the n⁺ type source layer 13, the p⁺ type contact layer 14, the p⁺ type contact layer 24a, the dummy trench electrode 12a, and the diode trench electrode 21a, respectively.

Next, as illustrated in FIG. 15B, the barrier metal 5 is formed on the front surface of the semiconductor substrate and the interlayer insulating film 4 in the IGBT region 10, and the silicon layer 51 containing oxygen is formed on the front surface of the semiconductor substrate in the diode region 20. The barrier metal 5 is formed by forming a film of titanium nitride by physical vapor deposition (PVD) or CVD. The silicon layer 51 is formed by plasma treatment or WET treatment in an atmosphere containing oxygen. An oxygen density of the silicon layer 51 formed in this manner is lower than an oxygen density of a silicon layer formed by thermal diffusion or CVD. The oxygen density of the silicon layer 51 can be adjusted by an oxygen concentration of the atmosphere during treatment and a type of treatment for forming the silicon layer 51. Note that a thickness of the silicon layer 51 is preferably equal to or less than a half of a height of the first silicon nodule 52 to be formed in the next process.

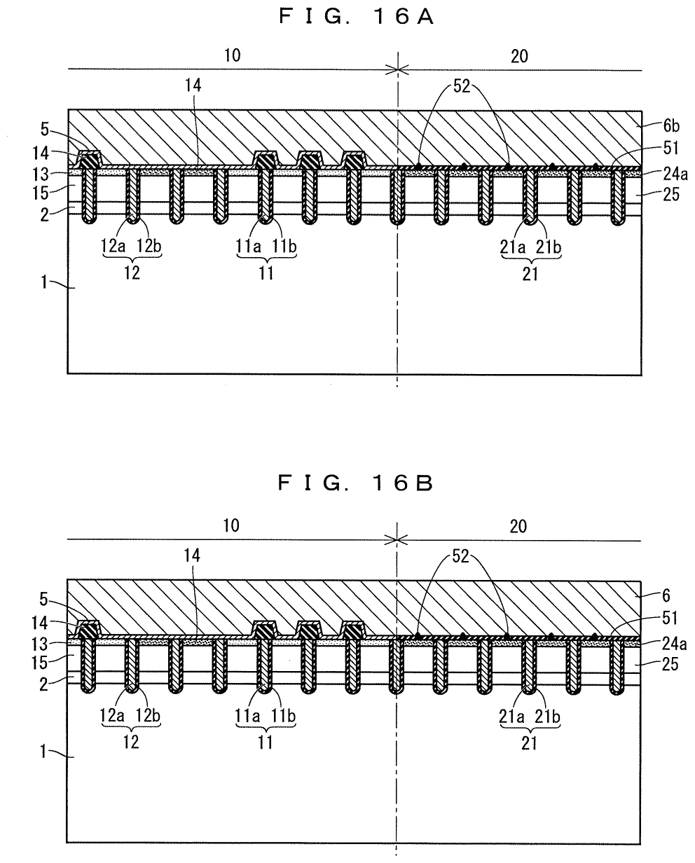

Next, as illustrated in FIG. 16A, a conductive film 6b containing silicon and aluminum is formed on the barrier metal 5 and the silicon layer 51 by performing sputtering of aluminum silicon (for example, an aluminum silicon alloy). A growth temperature of the sputtering is adjusted to form the first silicon nodule 52 containing oxygen between the p-type anode layer 25 and the conductive film 6b while forming the conductive film 6b. As the growth temperature of the sputtering is higher, the first silicon nodule 52 is more likely to be generated at a silicon substrate interface, interdiffusion is more likely to occur between the aluminum silicon and the silicon layer 51, and an alloy spike (that is, an aluminum spike) is more likely to be formed. For this reason, the growth temperature of the sputtering is appropriately set in consideration of these. Since the interdiffusion also occurs between the first silicon nodule 52 and aluminum, the first silicon nodule 52 usually contains aluminum and has a p-type conductivity.

If a flow rate of an atmosphere gas (an argon gas, a hydrogen gas, or the like) of the sputtering is adjusted, oxygen on the surface of the silicon layer 51 is reduced, and the oxygen is taken into the aluminum silicon of the first silicon nodule 52. From the above, an oxygen concentration in the first silicon nodule 52 can be adjusted by adjusting a treatment temperature and a treatment atmosphere of the sputtering.

In the first preferred embodiment, the first silicon nodule 52 penetrates the silicon layer 51 in the thickness direction of the silicon layer 51. However, the silicon layer 51 does not need to remain, and may be removed if necessary, for example, after the formation of the first silicon nodule 52.

Next, although specific patterning is not illustrated in FIG. 16B, the emitter electrode 6 is formed by patterning the conductive film 6b by etching or the like.

Next, as illustrated in FIG. 17A, the back surface side of the semiconductor substrate is ground to thin the semiconductor substrate to a designed predetermined thickness. The thickness of the semiconductor substrate after the grinding may be, for example, 80 μm to 200 μm.

Next, as illustrated in FIG. 17B, n-type impurities are implanted from the back surface side of the semiconductor substrate to form the n-type buffer layer 3. Further, p-type impurities are implanted from the back surface side of the semiconductor substrate to form the p-type collector layer 16. The n-type buffer layer 3 may be formed in the IGBT region 10, the diode region 20, the termination region 30, and the like, or may be formed only in the IGBT region 10 or the diode region 20. The n-type buffer layer 3 may be formed, for example, by implanting phosphorus (P) ions, protons (H⁺), or both protons and phosphorus. Protons can be implanted from the back surface of the semiconductor substrate to a deep position with relatively low acceleration energy. In addition, a depth at which protons are implanted can be relatively easily changed by changing the acceleration energy. For this reason, if implantation is performed a plurality of times while changing the acceleration energy during formation of the n-type buffer layer 3 using protons, it is possible to form the n-type buffer layer 3 thicker in a thickness direction of the semiconductor substrate than that formed using phosphorus.

In addition, phosphorus can increase an activation rate as n-type impurities as compared with protons, and thus, if the n-type buffer layer 3 is formed using phosphorus, punch-through of a depletion layer can be suppressed even in the thinned semiconductor substrate. In order to further thin the semiconductor substrate, it is preferable to form the n-type buffer layer 3 by implanting both protons and phosphorus, and in this case, protons are implanted to a position deeper than that of phosphorus from the back surface.

The p-type collector layer 16 may be formed by implanting boron (B), for example. The p-type collector layer 16 is also formed in the termination region 30, and the p-type collector layer 16 in the termination region 30 is to be the p-type termination collector layer 16a. After ion implantation from the back surface side of the semiconductor substrate, the back surface is irradiated with a laser beam to perform laser annealing, whereby the implanted boron is activated to form the p-type collector layer 16. At this time, phosphorus implanted to a relatively shallow position from the back surface of the semiconductor substrate is also activated at the same time. On the other hand, protons are activated at a relatively low annealing temperature such as 350° C. to 500° C., and thus, it is necessary to pay attention such that the temperature of the entire semiconductor substrate does not become higher than 350° C. to 500° C. except for a process for activation of protons after the implantation of protons. The laser annealing can be used to activate n-type impurities and p-type impurities even after the implantation of protons since only the vicinity of the back surface of the semiconductor substrate can be heated to a high temperature.

Next, as illustrated in FIG. 18A, the n⁺ type cathode layer 26 is formed on the back surface side of the diode region 20. The n⁺ type cathode layer 26 may be formed by implanting, for example, arsenic (As), phosphorus (P), or the like. As illustrated in FIG. 18A, n-type impurities are selectively implanted from the back surface side by mask processing such that a boundary between the p-type collector layer 16 and the n⁺ type cathode layer 26 is located at a position at the distance U1 from a boundary between the IGBT region 10 and the diode region 20 toward the diode region 20. An implantation amount of n-type impurities for forming the n⁺ type cathode layer 26 is larger than an implantation amount of p-type impurities for forming the p-type collector layer 16. Although FIG. 18A illustrates the p-type collector layer 16 and the n⁺ type cathode layer 26 having the same depth from the back surface, but the depth of the n⁺ type cathode layer 26 is equal to or more than the depth of the p-type collector layer 16. Since it is necessary to implant n-type impurities into a region into which p-type impurities have been implanted to finally obtain an n-type in a region where the n⁺ type cathode layer 26 is to be formed, a concentration of the n-type impurities is higher than a concentration of the p-type impurities that have been implanted in the entire region where the n⁺ type cathode layer 26 is to be formed.

Next, as illustrated in FIG. 18B, the collector electrode 7 is formed on the back surface of the semiconductor substrate. The collector electrode 7 is formed over the entire surface of the IGBT region 10, the diode region 20, the termination region 30, and the like on the back surface. The collector electrode 7 may be formed over the entire back surface of a n-type wafer as the semiconductor substrate. The collector electrode 7 may be formed by depositing an aluminum silicon alloy (Al—Si-based alloy), titanium (Ti), or the like by PVD such as sputtering or vapor deposition, or may be formed by laminating a plurality of metals such as an aluminum silicon alloy, titanium, nickel, and gold. In addition, the collector electrode 7 may be formed by further forming a metal film on a metal film, which has been formed by PVD, by electroless plating or electrolytic plating.

The semiconductor device 100 is manufactured by the above processes. A plurality of the semiconductor devices 100 are manufactured in a state of being integrated in a matrix on the semiconductor substrate such as one n-type wafer. For this reason, the semiconductor devices 100 are individually cut by laser dicing or blade dicing.

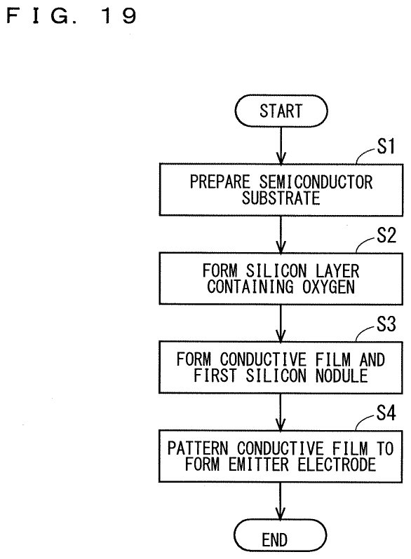

FIG. 19 is a flowchart illustrating main processes of forming the structure on the front surface side of the semiconductor device in the method of manufacturing the semiconductor device described above. In step S1, the semiconductor substrate that includes the n-type drift layer 1 and the p-type anode layer 25 and is provided with the interlayer insulating film 4 having contact holes is prepared by performing the processes of FIGS. 12A to 14B and FIG. 15A. In step S2, the silicon layer 51 containing oxygen is formed by performing the process of FIG. 15B. In step S3, the process of FIG. 16A, that is, sputtering of aluminum silicon is performed to form the first silicon nodule 52 containing oxygen while forming the conductive film 6b containing silicon and aluminum. In step S4, the conductive film 6b is patterned by performing the process of FIG. 16B to form the emitter electrode 6. Note that the conductive film 6b, that is, the emitter electrode 6 may be a single-layer film or a multi-layer film. As described above, the structure on the front surface side of the semiconductor device is formed.

### Summary of First Preferred Embodiment

With the semiconductor device according to the first preferred embodiment as described above, the first silicon nodule 52 containing oxygen is provided between the p-type anode layer 25 and the emitter electrode 6. According to such a configuration, the interdiffusion between silicon of the p-type anode layer 25 and aluminum of the emitter electrode 6 can be suppressed by the first silicon nodule 52, and thus, variation in a diffusion profile of the p-type anode layer 25 can be suppressed. In addition, a resistance value of the first silicon nodule 52 can be adjusted by adjusting the oxygen contained in the first silicon nodule 52, and as a result, resistance between the emitter electrode 6 and the p-type anode layer 25 can be adjusted. In addition, the first silicon nodule 52 can suppress the alloy spike.

In the first preferred embodiment, the first silicon nodule 52 penetrates the silicon layer 51 in the thickness direction of the silicon layer 51. According to such a configuration, the oxygen contained in the first silicon nodule 52 can be easily adjusted by the silicon layer 51, and the resistance between the emitter electrode 6 and the p-type anode layer 25 can be easily adjusted.

In the first preferred embodiment, the first silicon nodule 52 protrudes to the emitter electrode 6. According to such a configuration, a contact area between the first silicon nodule 52 and the emitter electrode 6 can be increased, and thus, contact resistance can be reduced.

### Second Preferred Embodiment

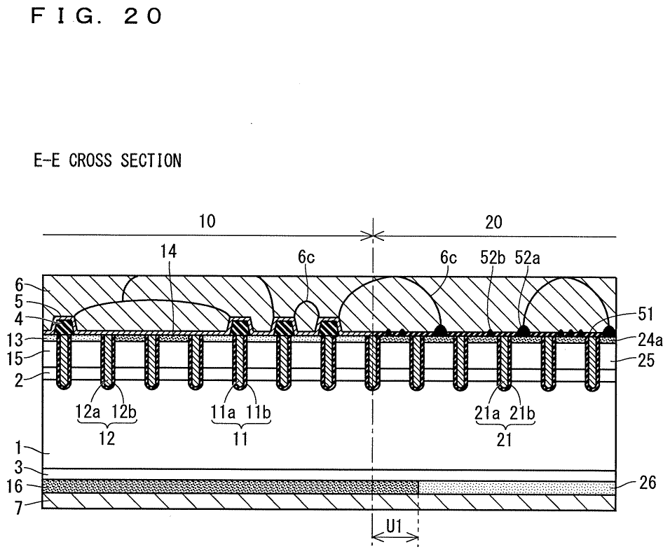

FIG. 20 is a cross-sectional view illustrating a configuration of a boundary region between the IGBT region 10 and the diode region 20 of a semiconductor device according to a second preferred embodiment.

In the second preferred embodiment, a plurality of the first silicon nodules 52 include first silicon nodules 52a and 52b having different grain sizes. As an example, a grain size of the first silicon nodule 52a located at a grain boundary 6c of the emitter electrode 6 is larger than a grain size of the first silicon nodule 52b located outside the grain boundary 6c. An oxygen concentration of the first silicon nodule 52a located at the grain boundary 6c of the emitter electrode 6 is higher than an oxygen concentration of the first silicon nodule 52b located outside the grain boundary 6c.

Note that a grain size of the emitter electrode 6 is equal to or smaller than a thickness of the emitter electrode 6. The emitter electrode 6 may be a single-layer film as in the first preferred embodiment, or may be a multi-layer film.

Next, a manufacturing method will be described. The grain sizes of the plurality of first silicon nodules 52 between the emitter electrode 6 and the p-type anode layer 25 are adjusted to the same extent by adjusting temperature in step S3 of FIG. 19 (that is, sputtering for forming the conductive film 6b and the like). When heat treatment is performed after the process of step S3 of FIG. 19 and the temperature and time of the heat treatment are adjusted, movement of the first silicon nodule 52 along the grain boundary 6c of the emitter electrode 6 is promoted. As a result, the grain size of the first silicon nodule 52a located at the grain boundary 6c of the emitter electrode 6 becomes larger than the grain size of the first silicon nodule 52b located outside the grain boundary 6c. When the treatment atmosphere, temperature, and time of the heat treatment after the process of step S3 in FIG. 19 are adjusted, movement of the first silicon nodule 52 and oxygen along the grain boundary 6c of the emitter electrode 6 is promoted.

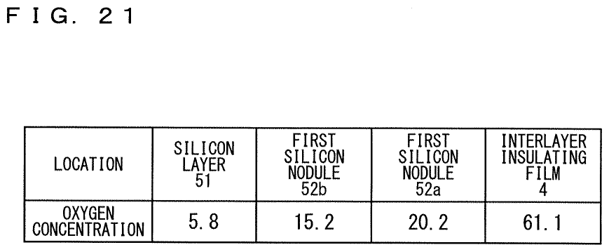

FIG. 21 is a view illustrating a result of analyzing and evaluating oxygen concentrations of first silicon nodules and the like by energy dispersive X-ray spectroscopy (EDS) in a representative structure using the above-described manufacturing method according to the second preferred embodiment. Note that the unit of numerical values is atm %. As can be seen from this result, according to the above manufacturing method, the oxygen concentration of the first silicon nodule 52a located at the grain boundary 6c of the emitter electrode 6 is higher than the oxygen concentration of the first silicon nodule 52b located outside the grain boundary 6c.

### Summary of Second Preferred Embodiment

With the semiconductor device according to the second preferred embodiment as described above, resistance between the emitter electrode 6 and the p-type anode layer 25 can be accurately adjusted since the grain sizes of the plurality of first silicon nodules 52 are different.

In the second preferred embodiment, the grain size of the first silicon nodule 52a located at the grain boundary 6c of the emitter electrode 6 is larger than the grain size of the first silicon nodule 52b located outside the grain boundary 6c. According to such a configuration, the resistance between the emitter electrode 6 and the p-type anode layer 25 can be adjusted by adjusting the grain boundary 6c of the emitter electrode 6.

In the second preferred embodiment, the oxygen concentration of the first silicon nodule 52a located at the grain boundary 6c of the emitter electrode 6 is higher than the oxygen concentration of the first silicon nodule 52b located outside the grain boundary 6c. According to such a configuration, the resistance between the emitter electrode 6 and the p-type anode layer 25 can be adjusted by adjusting the grain boundary 6c of the emitter electrode 6.

### Third Preferred Embodiment

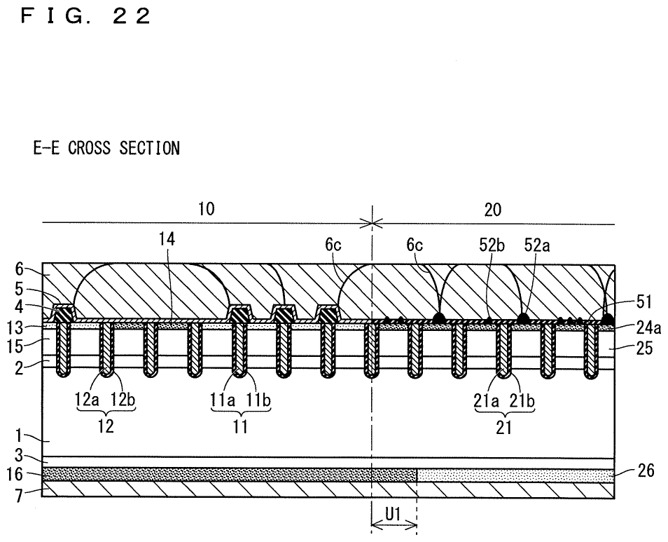

FIG. 22 is a cross-sectional view illustrating a configuration of a boundary region between the IGBT region 10 and the diode region 20 of a semiconductor device according to a third preferred embodiment.

In the third preferred embodiment, a grain size of the emitter electrode 6 is larger than a thickness of the emitter electrode 6, and upper portions of some grain boundaries 6c of the emitter electrode 6 are cut at an upper surface of the emitter electrode 6. The third preferred embodiment is similar to the second preferred embodiment except for this point. Such a configuration can be achieved by adjusting the grain size and thickness of the emitter electrode 6 by adjusting temperature and time in step S3 of FIG. 19 (that is, sputtering for forming the conductive film 6b and the like).

With the semiconductor device according to the third preferred embodiment, it is possible to reduce a component in the horizontal direction and increase a component in the vertical direction out of extending directions of the grain boundary 6c since the grain size of the emitter electrode 6 is larger than the thickness of the emitter electrode 6. As a result, movement of the first silicon nodule 52 along the grain boundary 6c of the emitter electrode 6 can be promoted, so that the grain size of the first silicon nodule 52a located at the grain boundary 6c of the emitter electrode 6 can be easily increased.

### Fourth Preferred Embodiment

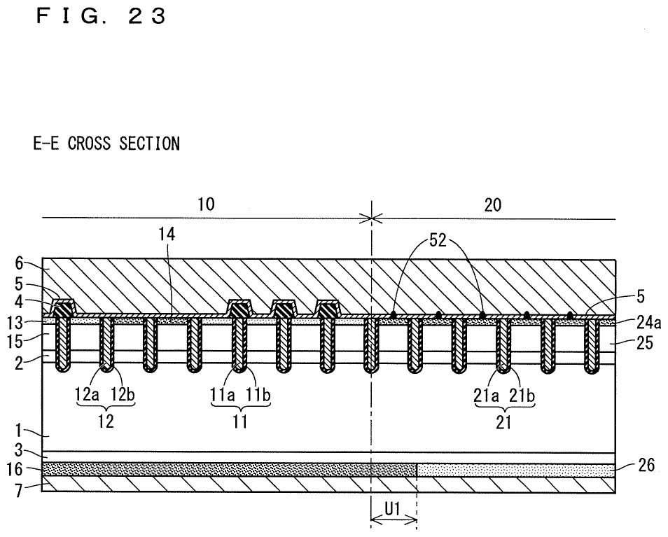

FIG. 23 is a cross-sectional view illustrating a configuration of a boundary region between the IGBT region 10 and the diode region 20 of a semiconductor device according to a fourth preferred embodiment.

In the semiconductor devices described so far, the barrier metal 5 is not provided in the diode region 20. On the other hand, in the semiconductor device according to the fourth preferred embodiment, the barrier metal 5 in ohmic contact with the diode trench electrode 21a and the p⁺ type contact layer 24a is provided between the p-type anode layer 25 and the emitter electrode 6, instead of the silicon layer 51. The first silicon nodule 52 penetrates the barrier metal 5 in a thickness direction of the barrier metal 5.

Next, a manufacturing method will be described. First, when the barrier metal 5 is formed in the IGBT region 10, the barrier metal 5 is also formed in the diode region 20. Next, holes reaching the surface of a semiconductor substrate are formed in the barrier metal 5 of the diode region 20 by performing etching processing or the like. Then, the first silicon nodules 52 are formed from the surface of the semiconductor substrate (the p⁺ type contact layer 24a in the example of FIG. 23) exposed from the holes of the barrier metal 5 by performing step S3 of FIG. 19 (that is, sputtering for forming the conductive film 6b and the like).

In the semiconductor device according to the fourth preferred embodiment, the first silicon nodule 52 penetrates the barrier metal 5 in the thickness direction of the barrier metal 5. According to such a configuration, resistance between the emitter electrode 6 and the p-type anode layer 25 can be adjusted also when the barrier metal 5 is provided in the diode region 20.

### Fifth Preferred Embodiment

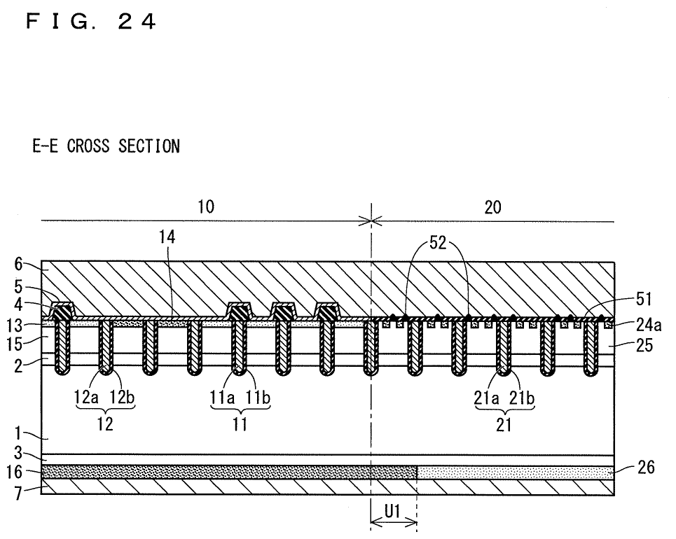

FIG. 24 is a cross-sectional view illustrating a configuration of a boundary region between the IGBT region 10 and the diode region 20 of a semiconductor device according to a fifth preferred embodiment.

In the fifth preferred embodiment, as in the first preferred embodiment, the diode region 20 that includes the p-type anode layer 25, functions as a diode, and is provided with the diode trench gate 21 is defined in a semiconductor substrate. In the fifth preferred embodiment, the p⁺ type contact layer 24a is partially provided on the p-type anode layer 25 in a cross section taken along a width direction of the diode trench gate 21. Note that the width direction of the diode trench gate 21 is a direction substantially perpendicular to an extending direction of the diode trench gate 21 (direction from the front side on the paper surface to the back side on the paper surface of FIG. 24).

In the fifth preferred embodiment, a ratio of the first silicon nodule 52 per unit area in the p-type anode layer 25 exposed from the p⁺ type contact layer 24a is larger than a ratio of the first silicon nodule 52 per unit area in the p⁺ type contact layer 24a. Note that the former ratio is a ratio of an area or the number of the first silicon nodules 52 provided between the p-type anode layer 25 and the emitter electrode 6 exposed from the p⁺ type contact layer 24a in plan view to an area of the p-type anode layer 25 in plan view. The latter ratio is a ratio of an area or the number of the first silicon nodules 52 provided between the p⁺ type contact layer 24a and the emitter electrode 6 in plan view to an area of the p⁺ type contact layer 24a in plan view.

Note that the above configuration is formed by adjusting a mask pattern for forming the p⁺ type contact layer 24a and appropriately selecting p-type impurities of the p⁺ type contact layer 24a.

With the semiconductor device according to the fifth preferred embodiment as described above, the p⁺ type contact layer 24a is partially provided on the p-type anode layer 25 in the cross section taken along the width direction of the diode trench gate 21. According to such a configuration, resistance between the emitter electrode 6 and the p-type anode layer 25 can be adjusted in a region where the p⁺ type contact layer 24a is not provided.

In addition, the ratio of the first silicon nodule 52 per unit area in the p-type anode layer 25 exposed from the p⁺ type contact layer 24a is larger than the ratio of the first silicon nodule 52 per unit area in the p⁺ type contact layer 24a in the fifth preferred embodiment. According to such a configuration, the resistance between the emitter electrode 6 and the p-type anode layer 25 can be reduced in the region of the p-type anode layer 25 where the p⁺ type contact layer 24a is not provided.

### Sixth Preferred Embodiment

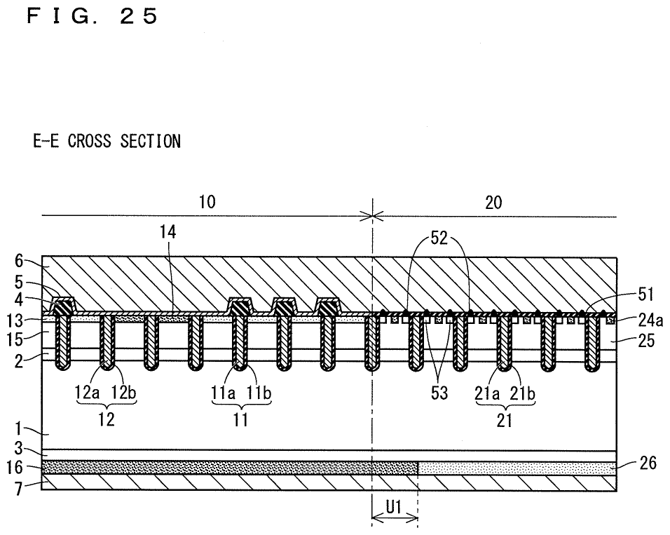

FIG. 25 is a cross-sectional view illustrating a configuration of a boundary region between the IGBT region 10 and the diode region 20 of a semiconductor device according to a sixth preferred embodiment.

A semiconductor substrate according to the sixth preferred embodiment further includes an n⁺ type impurity layer 53 partially provided on the p-type anode layer 25. The n⁺ type impurity layer 53 in the example of FIG. 25 is partially provided on the p-type anode layer 25 in a cross section taken along a width direction of the diode trench gate 21, which is similar to the p⁺ type contact layer 24a. Note that the n⁺ type impurity layer 53 may have a concentration that is the same or different from that of the n⁺ type source layer 13.

In the sixth preferred embodiment, a ratio of the first silicon nodule 52 per unit area in the n⁺ type impurity layer 53 is larger than a ratio of the first silicon nodule 52 per unit area in the p-type anode layer 25 exposed from the n⁺ type impurity layer 53. Note that the former ratio is a ratio of an area or the number of the first silicon nodules 52 provided between the n⁺ type impurity layer 53 and the emitter electrode 6 in plan view to an area of the n⁺ type impurity layer 53 in plan view. The latter ratio is a ratio of an area or the number of the first silicon nodules 52 provided between the p-type anode layer 25 and the emitter electrode 6 exposed from the n⁺ type impurity layer 53 in plan view to an area of the p-type anode layer 25 in plan view. The p-type anode layer 25 exposed from the n⁺ type impurity layer 53 may or may not include the p⁺ type contact layer 24.

Note that the above configuration is formed by adjusting a mask pattern for forming the n⁺ type impurity layer 53 and appropriately selecting n-type impurities of the n⁺ type impurity layer 53.

With the semiconductor device according to the sixth preferred embodiment as described above, the semiconductor substrate further includes the n⁺ type impurity layer 53 partially provided on the p-type anode layer. According to such a configuration, resistance between the emitter electrode 6 and the p-type anode layer 25 in a region where the n⁺ type impurity layer 53 is provided can be adjusted.

In addition, the ratio of the first silicon nodule 52 per unit area in the n⁺ type impurity layer 53 is larger than the ratio of the first silicon nodule 52 per unit area in the p-type anode layer 25 exposed from the n⁺ type impurity layer 53 in the sixth preferred embodiment. According to such a configuration, the resistance between the emitter electrode 6 and the p-type anode layer 25 can be reduced in the region where the n⁺ type impurity layer 53 is provided.

### Seventh Preferred Embodiment

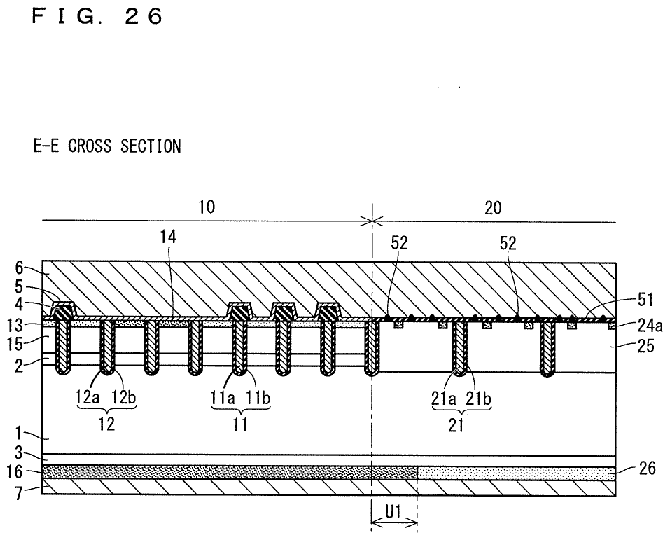

FIG. 26 is a cross-sectional view illustrating a configuration of a boundary region between the IGBT region 10 and the diode region 20 of a semiconductor device according to a seventh preferred embodiment.

In the seventh preferred embodiment, the diode region 20 that includes the p-type anode layer 25, functions as a diode, and is provided with the diode trench gates 21, and the IGBT region 10 that functions as an IGBT and is provided with trench gates are defined in a semiconductor substrate, which is similar to the first preferred embodiment. Note that the trench gate herein may be the active trench gate 11 or the dummy trench gate 12.

Here, the first silicon nodule 52 is usually not provided on the diode trench gate 21. In consideration of this, in the semiconductor device according to the seventh preferred embodiment, an interval between the diode trench gates 21 is larger than an interval between the trench gates, and the number of the diode trench gates 21 is reduced. According to such a configuration, the number of the first silicon nodules 52 provided in the diode region 20 can be increased, and thus, resistance between the emitter electrode 6 and the p-type anode layer 25 can be reduced.

### Eighth Preferred Embodiment

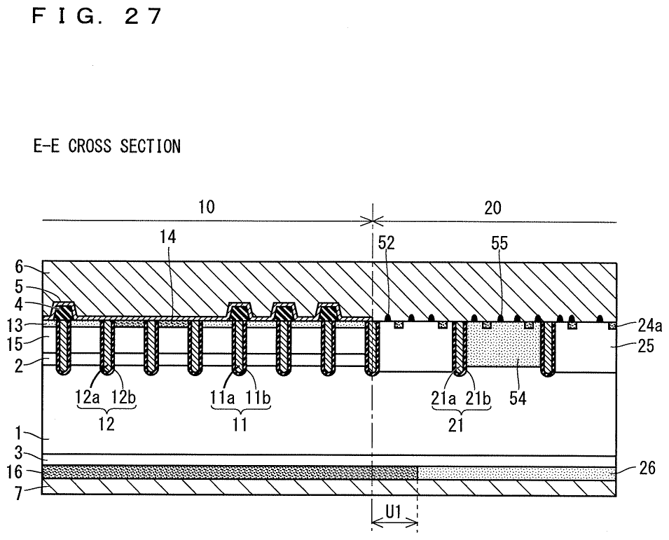

FIG. 27 is a cross-sectional view illustrating a configuration of a boundary region between the IGBT region 10 and the diode region 20 of a semiconductor device according to an eighth preferred embodiment.

A semiconductor substrate according to the eighth preferred embodiment further includes an n-type Schottky layer 54 that is Schottky connected to the emitter electrode 6. Note that the n-type Schottky layer 54 is directly provided on the n⁻ type drift layer 1 in FIG. 27, but may be indirectly provided on the n′ type drift layer 1. In the eighth preferred embodiment, a second silicon nodule 55 containing oxygen is provided between the n-type Schottky layer 54 and the emitter electrode 6.

With such a semiconductor device according to the eighth preferred embodiment, characteristics of a Schottky junction can be adjusted by the second silicon nodule 55 containing oxygen.

### Ninth Preferred Embodiment

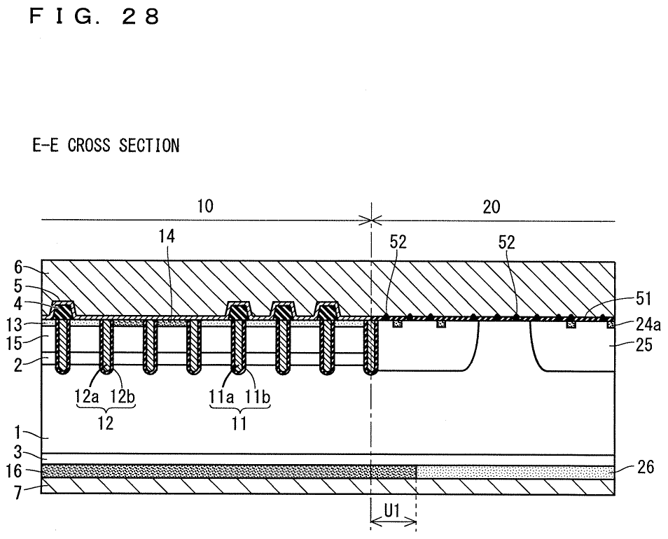

FIG. 28 is a cross-sectional view illustrating a configuration of a boundary region between the IGBT region 10 and the diode region 20 of a semiconductor device according to a ninth preferred embodiment.

In the above description, the diode region 20 that includes the p-type anode layer 25, functions as the diode, and is provided with the diode trench gate 21 is defined in the semiconductor substrate. On the other hand, in the ninth preferred embodiment, the diode region 20 that includes the p-type anode layer 25 and functions as a diode but is not provided with the diode trench gate 21 is defined in a semiconductor substrate. With such a semiconductor device according to the ninth preferred embodiment, there is no step due to the diode trench gate 21, and thus, the first silicon nodule 52 can be stably formed.

### Tenth Preferred Embodiment

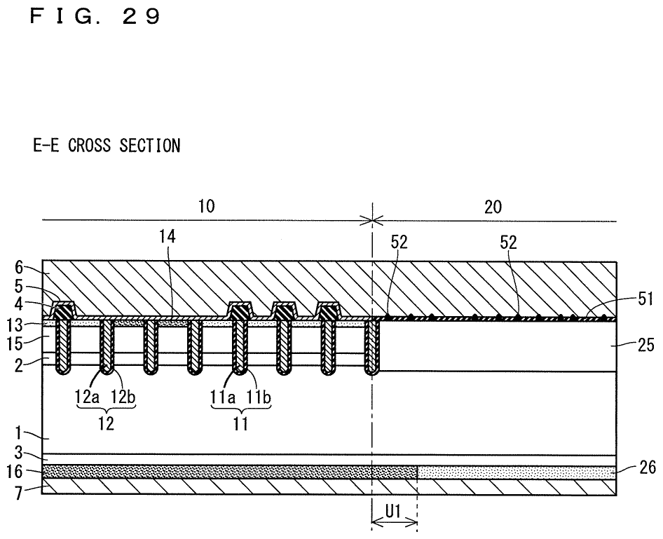

FIG. 29 is a cross-sectional view illustrating a configuration of a boundary region between the IGBT region 10 and the diode region 20 of a semiconductor device according to a tenth preferred embodiment.

In the tenth preferred embodiment, the p-type anode layer 25 is provided on an n⁻ type drift layer of the diode region 20, and the p⁺ type contact layer 24 is not provided. The tenth preferred embodiment is similar to the ninth preferred embodiment except for this point. According to such a configuration, as in the first preferred embodiment, interdiffusion between silicon of the p-type anode layer 25 and aluminum of the emitter electrode 6 can be suppressed, and the first silicon nodule 52 can suppress an alloy spike.

### Eleventh Preferred Embodiment

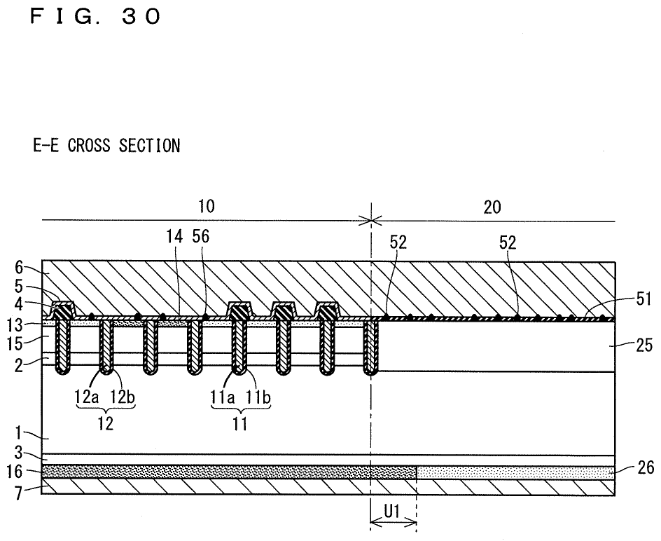

FIG. 30 is a cross-sectional view illustrating a configuration of a boundary region between the IGBT region 10 and the diode region 20 of a semiconductor device according to an eleventh preferred embodiment.

In the eleventh preferred embodiment, as in the first preferred embodiment, the diode region 20 that includes the p-type anode layer 25 and functions as a diode and the IGBT region 10 that functions as an IGBT are defined in a semiconductor substrate. The semiconductor substrate according to the eleventh preferred embodiment includes the p-type base layer 15 that is a base layer, the n⁺ type source layer 13 that is an emitter layer, and the p⁺ type contact layer 14 that is a second contact layer, which is similar to the semiconductor substrate according to the first preferred embodiment.

In the eleventh preferred embodiment, the emitter electrode 6 is provided above the p-type anode layer 25 and above at least one layer that is at least one of the p-type base layer 15, the n⁺ type source layer 13, and the p⁺ type contact layer 14 as in the first preferred embodiment. In the eleventh preferred embodiment, a third silicon nodule 56 containing oxygen is provided between the at least one layer and the emitter electrode 6. Note that the third silicon nodule 56 may also be provided in the IGBT region 10 in FIGS. 4 and 5.

With such a semiconductor device according to the eleventh preferred embodiment, resistance between the at least one layer and the emitter electrode 6 in the IGBT region 10 can be adjusted by the third silicon nodule 56 containing oxygen.

### <Modifications>

The semiconductor devices according to the first to sixth and eighth to tenth preferred embodiments are RC-IGBTs in which the IGBT region 10 and the diode region 20 are defined, but may be a single diode including the diode region 20 without the IGBT region 10. Although the silicon layer 51 is provided in some preferred embodiments of the first to eleventh preferred embodiments, the silicon layer 51 is not necessarily provided.

Note that each of the preferred embodiments and each of the modifications can be freely combined, and each of the preferred embodiments and each of the modifications can be appropriately modified or omitted.

Hereinafter, various aspects of the present disclosure will be collectively described as appendices.

### APPENDIX 1

A semiconductor device including:
a semiconductor substrate that includes a drift layer of a first conductivity type and an anode layer of a second conductivity type provided on at least a part of the drift layer;
an electrode provided above the anode layer and containing aluminum; and
a first silicon nodule provided between the anode layer and the electrode and containing oxygen.

### APPENDIX 2

The semiconductor device according to Appendix 1, wherein
the semiconductor substrate further includes a first contact layer of the second conductivity type that is provided on at least a part of the anode layer and has a higher impurity concentration of the second conductivity type than the anode layer.

### APPENDIX 3

The semiconductor device according to Appendix 1 or 2, further including a silicon layer provided between the anode layer and the electrode and containing oxygen,
wherein the first silicon nodule penetrates the silicon layer in a thickness direction of the silicon layer.

### APPENDIX 4

The semiconductor device according to any one of Appendices 1 to 3, wherein
the first silicon nodule protrudes to the electrode.

### APPENDIX 5

The semiconductor device according to any one of Appendices 1 to 4, wherein
the plurality of first silicon nodules have different grain sizes.

### APPENDIX 6

The semiconductor device according to any one of Appendices 1 to 5, wherein
among the plurality of first silicon nodules, a grain size of the first silicon nodule located at a grain boundary of the electrode is larger than a grain size of the first silicon nodule located outside the grain boundary.

### APPENDIX 7

The semiconductor device according to any one of Appendices 1 to 5, wherein
among the plurality of first silicon nodules, an oxygen concentration of the first silicon nodule located at a grain boundary of the electrode is higher than an oxygen concentration of the first silicon nodule located outside the grain boundary.

### APPENDIX 8

The semiconductor device according to any one of Appendices 1 to 7, wherein
a grain size of the electrode is larger than a thickness of the electrode.

### APPENDIX 9

The semiconductor device according to Appendix 1 or 2, further including
a barrier metal provided between the anode layer and the electrode,
wherein the first silicon nodule penetrates the barrier metal in a thickness direction of the barrier metal.

### APPENDIX 10

The semiconductor device according to any one of Appendices 2 to 9, wherein
a diode region, which includes the anode layer, functions as a diode, and is provided with a diode trench gate, is defined in the semiconductor substrate, and
the first contact layer is partially provided on the anode layer in a cross section taken along a width direction of the diode trench gate.

### APPENDIX 11

The semiconductor device according to Appendix 10, wherein
among the plurality of first silicon nodules, a ratio per unit area of the first silicon nodule provided between the anode layer exposed from the first contact layer and the electrode is larger than a ratio per unit area of the first silicon nodule provided between the first contact layer and the electrode.

### APPENDIX 12

The semiconductor device according to any one of Appendices 1 to 11, wherein
the semiconductor substrate further includes an impurity layer of the first conductivity type partially provided on the anode layer.

### APPENDIX 13

The semiconductor device according to Appendix 12, wherein
among the plurality of first silicon nodules, a ratio per unit area of the first silicon nodule provided between the impurity layer and the electrode is larger than a ratio per unit area of the first silicon nodule provided between the anode layer exposed from the impurity layer and the electrode.

### APPENDIX 14

The semiconductor device according to any one of Appendices 1 to 13, wherein
a diode region, which includes the anode layer, functions as a diode, and is provided with diode trench gates, and an IGBT region, which functions as an IGBT and is provided with trench gates, are defined in the semiconductor substrate, and
an interval between the diode trench gates is larger than an interval between the trench gates.

### APPENDIX 15

The semiconductor device according to any one of Appendices 1 to 14, wherein
the semiconductor substrate further includes a Schottky layer of the first conductivity type selectively provided on the drift layer and Schottky connected to the electrode,
the semiconductor device further including a second silicon nodule provided between the Schottky layer and the electrode and containing oxygen.

### APPENDIX 16

The semiconductor device according to any one of Appendices 1 to 13, wherein
a diode region, which includes the anode layer, functions as a diode, and is not provided with a diode trench gate, is defined in the semiconductor substrate.

### APPENDIX 17

The semiconductor device according to any one of Appendices 1 to 13, wherein
a diode region including the anode layer and functioning as a diode and an IGBT region functioning as an IGBT are defined in the semiconductor substrate,
the semiconductor substrate further includes:
   a base layer of the second conductivity type selectively provided on the drift layer of the IGBT region; and
   an emitter layer of the first conductivity type and a second contact layer of the second conductivity type having a higher impurity concentration of the second conductivity type than the base layer, the emitter layer and the second contact layer being selectively provided on the base layer, and
the electrode is provided above the anode layer and above at least one layer that is at least one of the base layer, the emitter layer, and the second contact layer,
the semiconductor device further including a third silicon nodule provided between the at least one layer and the electrode and containing oxygen.

### APPENDIX 18

A method of manufacturing a semiconductor device, the method including:
a process of preparing a semiconductor substrate that includes a drift layer of a first conductivity type and an anode layer of a second conductivity type provided on at least a part of the drift layer;
a process of forming a silicon layer containing oxygen on an upper surface of the semiconductor substrate;
a process of forming a conductive film containing silicon and aluminum on the silicon layer and forming a first silicon nodule containing oxygen between the anode layer and the conductive film; and
a process of patterning the conductive film to form an electrode.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate that includes a drift layer of a first conductivity type and an anode layer of a second conductivity type provided on at least a part of the drift layer;
an electrode provided above the anode layer and containing aluminum; and
a first silicon nodule provided between the anode layer and the electrode and containing oxygen.

2. The semiconductor device according to claim 1, wherein
the semiconductor substrate further includes a first contact layer of the second conductivity type that is provided on at least a part of the anode layer and has a higher impurity concentration of the second conductivity type than the anode layer.

3. The semiconductor device according to claim 1, further comprising a silicon layer provided between the anode layer and the electrode and containing oxygen,
wherein the first silicon nodule penetrates the silicon layer in a thickness direction of the silicon layer.

4. The semiconductor device according to claim 1, wherein
the first silicon nodule protrudes to the electrode.

5. The semiconductor device according to claim 1, wherein
the plurality of first silicon nodules have different grain sizes.

6. The semiconductor device according to claim 1, wherein
among the plurality of first silicon nodules, a grain size of the first silicon nodule located at a grain boundary of the electrode is larger than a grain size of the first silicon nodule located outside the grain boundary.

7. The semiconductor device according to claim 1, wherein
among the plurality of first silicon nodules, an oxygen concentration of the first silicon nodule located at a grain boundary of the electrode is higher than an oxygen concentration of the first silicon nodule located outside the grain boundary.

8. The semiconductor device according to claim 1, wherein
a grain size of the electrode is larger than a thickness of the electrode.

9. The semiconductor device according to claim 1, further comprising a barrier metal provided between the anode layer and the electrode,
wherein the first silicon nodule penetrates the barrier metal in a thickness direction of the barrier metal.

10. The semiconductor device according to claim 2, wherein
a diode region, which includes the anode layer, functions as a diode, and is provided with a diode trench gate, is defined in the semiconductor substrate, and
the first contact layer is partially provided on the anode layer in a cross section taken along a width direction of the diode trench gate.

11. The semiconductor device according to claim 10, wherein
among the plurality of first silicon nodules, a ratio per unit area of the first silicon nodule provided between the anode layer exposed from the first contact layer and the electrode is larger than a ratio per unit area of the first silicon nodule provided between the first contact layer and the electrode.

12. The semiconductor device according to claim 1, wherein
the semiconductor substrate further includes an impurity layer of the first conductivity type partially provided on the anode layer.

13. The semiconductor device according to claim 12, wherein
among the plurality of first silicon nodules, a ratio per unit area of the first silicon nodule provided between the impurity layer and the electrode is larger than a ratio per unit area of the first silicon nodule provided between the anode layer exposed from the impurity layer and the electrode.

14. The semiconductor device according to claim 1, wherein
a diode region, which includes the anode layer, functions as a diode, and is provided with diode trench gates, and an IGBT region, which functions as an IGBT and is provided with trench gates, are defined in the semiconductor substrate, and
an interval between the diode trench gates is larger than an interval between the trench gates.

15. The semiconductor device according to claim 1, wherein
the semiconductor substrate further includes a Schottky layer of the first conductivity type selectively provided on the drift layer and Schottky connected to the electrode,
the semiconductor device further comprising a second silicon nodule provided between the Schottky layer and the electrode and containing oxygen.

16. The semiconductor device according to claim 1, wherein
a diode region, which includes the anode layer, functions as a diode, and is not provided with a diode trench gate, is defined in the semiconductor substrate.

17. The semiconductor device according to claim 1, wherein
a diode region including the anode layer and functioning as a diode and an IGBT region functioning as an IGBT are defined in the semiconductor substrate,
the semiconductor substrate further includes:
a base layer of the second conductivity type selectively provided on the drift layer of the IGBT region; and
an emitter layer of the first conductivity type and a second contact layer of the second conductivity type having a higher impurity concentration of the second conductivity type than the base layer, the emitter layer and the second contact layer being selectively provided on the base layer, and
the electrode is provided above the anode layer and above at least one layer that is at least one of the base layer, the emitter layer, and the second contact layer,
the semiconductor device further comprising a third silicon nodule provided between the at least one layer and the electrode and containing oxygen.

18. A method of manufacturing a semiconductor device, the method comprising:
preparing a semiconductor substrate that includes a drift layer of a first conductivity type and an anode layer of a second conductivity type provided on at least a part of the drift layer;
forming a silicon layer containing oxygen on an upper surface of the semiconductor substrate;
forming a conductive film containing silicon and aluminum on the silicon layer and forming a first silicon nodule containing oxygen between the anode layer and the conductive film; and
patterning the conductive film to form an electrode.
